(19) United States
(12) Patent Application Publication
(10) Pub. No.: US 2026/0198179 A1
(43) Pub. Date: Jul. 9, 2026

(54) DISPLAY DEVICE AND ELECTRONIC DEVICE

(71) Applicant: SAMSUNG DISPLAY CO., LTD., YONGIN-SI (KR)

(72) Inventors: Ji Seon LEE, Yongin-si (KR); Hyun Il KANG, Yongin-si (KR); Kyung Hae PARK, Yongin-si (KR); Ki Hwan SEOK, Yongin-si (KR); Se Wan SON, Yongin-si (KR); Jin Sung AN, Yongin-si (KR); Min Woo WOO, Yongin-si (KR); Seung Hyun LEE, Yongin-si (KR); Wang Woo LEE, Yongin-si (KR); Hye Ri CHO, Yongin-si (KR)

(21) Appl. No.: 19/363,889

(22) Filed: Oct. 21, 2025

(30) Foreign Application Priority Data
Jan. 6, 2025 (KR) 10-2025-0001721

(51) Int. Cl. H10K 59/121; H10D 86/40; H10D 86/60; H10H 29/32

(52) U.S. Cl. CPC H10K 59/1213; H10D 86/423; H10D 86/481; H10D 86/60; H10H 29/32; H10K 59/1216

(57) ABSTRACT

A display device includes a pixel including a first transistor and a first capacitor arranged to overlap each other on a substrate. The first capacitor includes a first capacitor electrode disposed on the substrate, a second capacitor electrode disposed on a first insulating layer covering the first capacitor electrode, and a third capacitor electrode disposed on a second insulating layer covering the second capacitor electrode and electrically connected to the first capacitor electrode. The first transistor includes a first active layer disposed on a third insulating layer covering the third capacitor electrode, the first active layer including a channel region, a first electrode region disposed at a side of the channel region, and a second electrode region disposed at another side of the channel region and electrically connected to the third capacitor electrode, and a first gate electrode disposed on a fourth insulating layer covering the channel region.

### CROSS-REFERENCE TO RELATED APPLICATIONS

This application claims priority under 35 U.S.C. § 119 to Korean Patent Application No. 10-2025-0001721, filed on Jan. 6, 2025, the disclosure of which is incorporated by reference in its entirety.

### TECHNICAL FIELD

Embodiments of the present disclosure relate to a display device and an electronic device capable of displaying an image.

### DISCUSSION OF RELATED ART

As society becomes increasingly information-oriented, the demand for display devices and electronic devices capable of presenting images in diverse ways continues to grow. In response, a wide variety of display technologies and image-display devices, each incorporating pixels for rendering images, are being developed. A display device may be used on its own or integrated into an electronic device to serve as its display screen.

### SUMMARY

Embodiments of the present disclosure provide a display device and an electronic device capable of efficiently arranging circuit elements of pixels and improving the operating characteristics of the pixels. However, embodiments of the present disclosure are not limited thereto.

According to an embodiment of the present disclosure, a display device includes a substrate and a pixel disposed on the substrate. The pixel includes a first transistor and a first capacitor that overlap each other. The first capacitor includes a first capacitor electrode disposed on the substrate, a second capacitor electrode disposed on a first insulating layer disposed between the first capacitor electrode and the second capacitor electrode, and a third capacitor electrode disposed on a second insulating layer disposed between the second capacitor electrode and the third capacitor electrode, and electrically connected to the first capacitor electrode. The first transistor includes a first active layer disposed on a third insulating layer disposed between the first active layer and the third capacitor electrode. The first active layer includes a channel region, a first electrode region disposed at a side of the channel region, and a second electrode region disposed at another side of the channel region. The first transistor further includes a gate electrode disposed on a fourth insulating layer disposed between the channel region and the gate electrode. The third capacitor electrode is electrically connected to the second electrode region and is configured to function as a sub-gate electrode to adjust a current-voltage characteristic of the first transistor.

In an embodiment, the first capacitor electrode includes a first semiconductor material and a conductive dopant doped into the first semiconductor material.

In an embodiment, the first active layer includes a second semiconductor material different from the first semiconductor material.

In an embodiment, the first semiconductor material includes a polycrystalline silicon, and the second semiconductor material includes an oxide semiconductor.

In an embodiment, each of the second capacitor electrode and the third capacitor electrode includes a conductive material.

In an embodiment, the gate electrode is electrically connected to the second capacitor electrode.

In an embodiment, the third capacitor electrode and the gate electrode face each other, and the channel region of the first active layer is interposed between the third capacitor electrode and the gate electrode.

In an embodiment, the pixel further includes a first switching transistor including a second active layer disposed in a same first layer as the first active layer.

In an embodiment, the first capacitor electrode includes a first portion overlapping the first transistor and a second portion overlapping the first switching transistor.

In an embodiment, the pixel further includes a second capacitor including a second portion of the first capacitor electrode and a fourth capacitor electrode overlapping the second portion of the first capacitor electrode.

In an embodiment, the first active layer and the second active layer include an oxide semiconductor.

In an embodiment, the pixel further includes a second switching transistor including a third active layer disposed in a same second layer as the first capacitor electrode.

In an embodiment, the first capacitor electrode and the third active layer include a polycrystalline silicon.

In an embodiment, the pixel further includes a light-emitting element electrically connected to a pixel circuit including the first transistor and the first capacitor.

According to an embodiment of the present disclosure, an electronic device includes a display device including a display panel, a memory configured to store an image data signal or an input control signal, and a processor configured to transmit the image data signal or the input control signal stored in the memory to the display device. The display panel includes a substrate, and a pixel disposed on the substrate and including a first transistor and a first capacitor that overlap each other. The first capacitor includes a first capacitor electrode disposed on the substrate, a second capacitor electrode disposed on a first insulating layer disposed between the first capacitor electrode and the second capacitor electrode, and a third capacitor electrode disposed on a second insulating layer disposed between the second capacitor electrode and the third capacitor electrode, and electrically connected to the first capacitor electrode. The first transistor includes a first active layer disposed on a third insulating layer disposed between the first active layer and the third capacitor electrode. The first active layer includes a channel region, a first electrode region disposed at a side of the channel region, and a second electrode region disposed at another side of the channel region. The first transistor further includes a gate electrode disposed on a fourth insulating layer disposed between the channel region and the gate electrode. The third capacitor electrode is electrically connected to the second electrode region and is configured to function as a sub-gate electrode to adjust a current-voltage characteristic of the first transistor.

In an embodiment, the first capacitor electrode includes a first semiconductor material and a conductive dopant doped into the first semiconductor material.

In an embodiment, the first active layer includes a second semiconductor material different from the first semiconductor material, the first semiconductor material includes a polycrystalline silicon, and the second semiconductor material includes an oxide semiconductor.

In an embodiment, the third capacitor electrode and the gate electrode face each other, and the channel region of the first active layer is interposed between the third capacitor electrode and the gate electrode.

In an embodiment, the pixel further includes a first switching transistor including a second active layer disposed in a same layer as the first active layer, and the first capacitor electrode includes a first portion overlapping the first transistor and a second portion overlapping the first switching transistor.

In an embodiment, the pixel further includes a second capacitor including a second portion of the first capacitor electrode and a fourth capacitor electrode overlapping the second portion of the first capacitor electrode.

A pixel according to embodiments of the present disclosure may include a first transistor, and a third capacitor electrode disposed under an active layer of the first transistor and electrically connected to a second electrode region of the first transistor. In some embodiments, the pixel may further include a first capacitor electrode disposed under the third capacitor electrode and electrically connected to the third capacitor electrode, and a second capacitor electrode disposed between the first capacitor electrode and the third capacitor electrode.

In some embodiments, the first capacitor electrode may be formed in the same layer as active layers of some transistors formed in a backplane layer of a display panel by using a first semiconductor material, for example, polycrystalline silicon, included in the active layers of those transistors. In some embodiments, the active layer of the first transistor may include a second semiconductor material, for example, an oxide semiconductor, which may result in improved reliability.

According to embodiments, the circuit elements of the pixel may be efficiently arranged or formed, and the operating characteristics of the pixel may be improved. As a result, the image quality and reliability of a display device and an electronic device including the pixel may be improved.

### BRIEF DESCRIPTION OF THE DRAWINGS

The above and other aspects and features of the present disclosure will become more apparent by describing in detail embodiments thereof with reference to the accompanying drawings, in which:

FIG. 1 is a perspective view illustrating a display device according to an embodiment;

FIG. 2 is a perspective view illustrating a display module according to an embodiment;

FIG. 3 is a plan view illustrating a display panel according to an embodiment;

FIG. 4 is a cross-sectional view illustrating a display module according to an embodiment;

FIG. 5 is a block diagram illustrating a display device according to an embodiment;

FIG. 6 is an equivalent circuit diagram illustrating a sub-pixel according to an embodiment;

FIG. 7 is a cross-sectional view illustrating a display panel according to an embodiment;

FIG. 8 is a plan view illustrating a part of a sub-pixel according to an embodiment;

FIG. 9 is a cross-sectional view illustrating a cross-section of a sub-pixel according to an embodiment;

FIG. 10 is a block diagram of an electronic device according to an embodiment; and

FIG. 11 illustrates schematic views of electronic devices according to various embodiments.

### DETAILED DESCRIPTION OF THE EMBODIMENTS

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Embodiments of the present disclosure relate to display devices, and more particularly, to a pixel structure in which a transistor and a capacitor are vertically integrated, which may reduce layout area and improve electrical performance. In an embodiment, the pixel includes a first transistor and a first capacitor arranged to overlap each other on a substrate.

The first capacitor may include three electrodes stacked with insulating layers interposed therebetween, including a third capacitor electrode that is electrically connected to both the first capacitor electrode and to the source or drain region of the first transistor. The first transistor may include an active layer, a gate electrode, and a sub-gate structure formed by the third capacitor electrode. This sub-gate structure may enable control of the current-voltage characteristics of the transistor by adjusting its subthreshold behavior.

This configuration may allow the third capacitor electrode to serve dual functions, e.g., as part of the storage capacitor and as a sub-gate electrode, which may improve transistor control without increasing the footprint of the pixel. Through this integration, embodiments may enable improved image quality and circuit compactness, especially in high-resolution display applications.

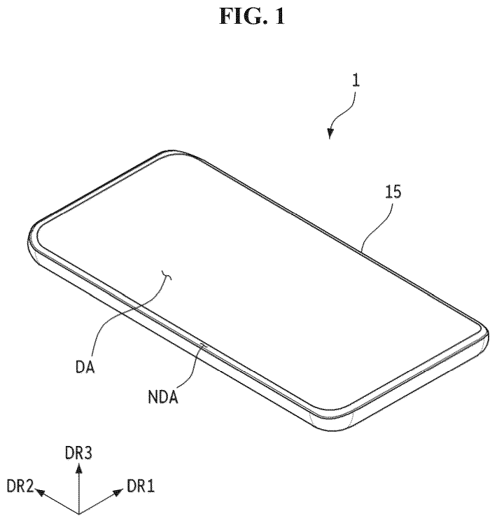

FIG. 1 is a perspective view illustrating a display device according to an embodiment.

Referring to FIG. 1, a display device 1 may be a device capable of providing an image such as, for example, a moving image (e.g., a video) or a still image. For example, the display device 1 may be an electronic device that includes a display module that implements a display screen and thus may display an image. For example, the display device 1 may be included in an electronic device that provides a display screen and may form the display screen of the electronic device. As an example, the display device 1 may refer to all electronic devices that provide a display screen on which an image may be displayed or include a display module for displaying an image.

In an embodiment, the display device may be a light-emitting display device including a light-emitting element such as, for example, an inorganic light-emitting diode or an organic light-emitting diode, but is not limited thereto. For example, in the present disclosure, a light-emitting display device including an organic light-emitting diode is disclosed as a display device to which embodiments may be applied, but the type or form of the display device to which embodiments may be applied is not limited thereto.

In an embodiment, the display device 1 may further include an additional element in addition to the display module. For example, the display device 1 may further include a housing 15 (or a casing) that stores and/or protects the display module. In FIG. 1, a portion of the display device 1 surrounded by the housing 15 (for example, a portion including a display area DA and a non-display area NDA) may include a display module including a display panel, and may further include a cover window disposed on the display panel.

The display device 1 may have various shapes such as, for example, a rectangle, a square, a circle, or the like. The display device 1 may include corner portions having an angled or rounded shape. In FIG. 1, the display device 1 is illustrated as having a roughly rectangular shape on a plane defined by a first direction DR1 and a second direction DR2 and having rounded corner portions. The display device 1 may have a thickness in a third direction DR3 intersecting the first direction DR1 and the second direction DR2.

The display device 1 may include the display area DA and the non-display area NDA. The display area DA is an area in which an image can be displayed, and the non-display area NDA is an area where an image is not displayed. The display area DA may also be referred to as an active region, and the non-display area NDA may also be referred to as a non-active region. The display area DA may substantially occupy the center of the display device 1. The non-display area NDA may be disposed around the display area DA. In an embodiment, the non-display area NDA may be disposed at the edge of the display device 1 to surround the display area DA.

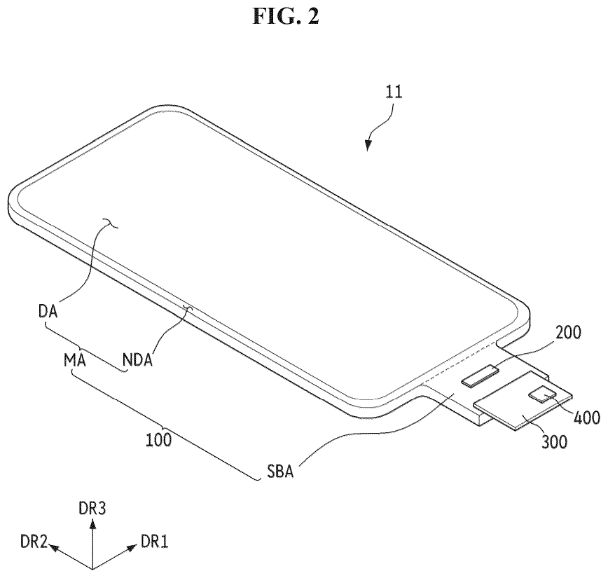

FIG. 2 is a perspective view illustrating a display module according to an embodiment. For example, FIG. 2 shows an embodiment of a display module 11 that may be included in the display device 1 of FIG. 1.

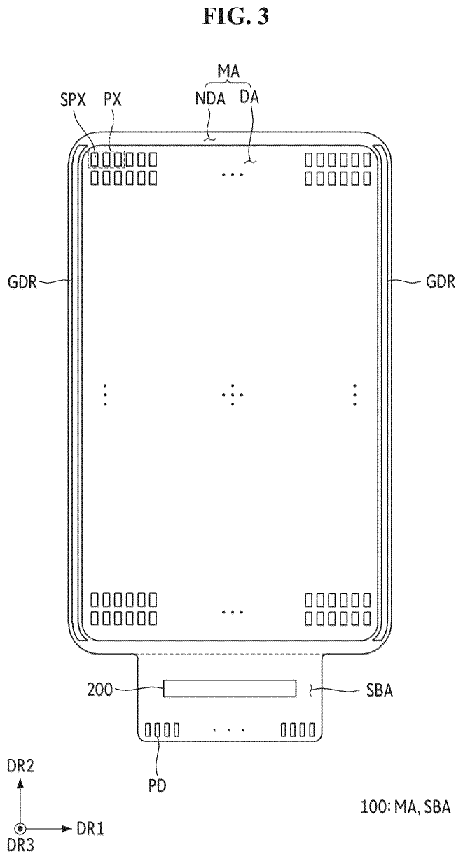

FIG. 3 is a plan view illustrating a display panel according to an embodiment. For example, FIG. 3 shows an embodiment of a display panel 100 that may be included in the display module 11 of FIG. 2.

FIGS. 2 and 3 show the display panel 100 including a sub-region SBA, and illustrate a state in which the sub-region SBA of the display panel 100 is unfolded without being bent. The display panel 100 may be accommodated inside the housing 15 of FIG. 1 by being bent so that a portion of the sub-region SBA overlaps a main region MA.

Referring to FIGS. 1 to 3, the display device 1 may include the display module 11. The display module 11 may include the display panel 100 that implements a display screen, and a display driver 200 and a circuit board 300 that drive the display panel 100. In an embodiment, the display device 1 may provide a touch input function, and the display module 11 may further include a touch driver 400.

The display panel 100 may include the main region MA including the display area DA. The main region MA may further include the non-display area NDA provided around the display area DA.

A plurality of pixels PX that display an image may be arranged in the display area DA. Each of the pixels PX may include a plurality of sub-pixels SPX. The pixel PX may be defined as a minimum unit sub-pixel group capable of expressing a white grayscale.

In an embodiment, each of the pixels PX may include three sub-pixels SPX including a first sub-pixel that emits light of a first color, a second sub-pixel that emits light of a second color, and a third sub-pixel that emits light of a third color. In an embodiment, the light of the first color, the light of the second color, and the light of the third color may be red light (for example, light in a red wavelength band having a main peak wavelength of about 600 nm to about 750 nm), green light (for example, light in a green wavelength band having a main peak wavelength of about 480 nm to about 560 nm), and blue light (for example, light in a blue wavelength band having a main peak wavelength of about 370 nm to about 460 nm), respectively. However, embodiments are not limited thereto, and the number, type, arrangement structure, and/or emission wavelength of the sub-pixels SPX included in each of the pixels PX may be changed in various ways according to embodiments.

In an embodiment, the sub-pixels SPX (or the pixels PX including the sub-pixels SPX) may be arranged in a matrix form in the display area DA along the first direction DR1 and the second direction DR2. However, the arrangement structure or arrangement direction of the sub-pixels SPX and the pixels PX may be changed in various ways according to embodiments.

A pixel area in which each pixel PX is disposed may include emission areas of the sub-pixels SPX that constitute each pixel PX. When the display panel 100 is a light-emitting display panel including light-emitting elements, each sub-pixel may include at least one light-emitting element disposed in each emission area. Each sub-pixel may further include a pixel circuit that controls the light-emitting element. In this case, each pixel area may include pixel circuit areas where the pixel circuits of the sub-pixels SPX that constitute each pixel PX are arranged. In an embodiment, the emission areas and the pixel circuit areas of each pixel PX may overlap each other, but the present disclosure is not limited thereto.

Wires connected to the pixels PX may be arranged in the non-display area NDA. For example, wires connecting the pixels PX to the display driver 200 may be arranged in the non-display area NDA. Wires connecting the pixels PX to a pad portion and/or wires connecting display driver 200 to the pad portion may be further arranged in the non-display area NDA.

In an embodiment, at least one driving circuit that drives the pixels PX may be further disposed in the non-display area NDA. For example, at least one gate driver GDR may be disposed in the non-display area NDA. FIG. 3 illustrates an embodiment in which two gate drivers GDR are arranged in the non-display area NDA on opposite sides of the display area DA, but the number and/or positions of the gate drivers GDR are not limited thereto.

In an embodiment, the gate driver GDR may be a panel-embedded driving circuit formed inside the display panel 100 together with the pixels PX. For example, the gate driver GDR may include circuit elements formed within the backplane layer of the display panel 100 together with the circuit elements included in the pixel circuits of the pixels PX. At least some of the circuit elements of the gate driver GDR (for example, circuit elements of stage circuits that generate respective gate signals including scan signals and emission control signals) and the circuit elements included in the pixel circuits of the pixels PX may be formed substantially simultaneously.

In an embodiment, the display panel 100 may further include the sub-region SBA extending from the main region MA. The sub-region SBA may be a region extending from one side of the main region MA. In an embodiment, the sub-region SBA may have flexible characteristics so as to be bent, folded, or rolled. When the sub-region SBA is bent (or folded), at least a portion of the sub-region SBA and the main region MA may overlap each other in a thickness direction (e.g., the third direction DR3). For example, when the display panel 100 is bent in the sub-region SBA, at least a portion of the sub-region SBA including an area where the display driver 200 is disposed and an area where pads PD connected to the circuit board 300 are arranged may be disposed under the main region MA.

In an embodiment, the sub-region SBA may include the display driver 200 and the pad portion. The pad portion may be an area where the pads PD electrically connected to the circuit board 300 are arranged.

In an embodiment, the sub-region SBA may be omitted, and the pad portion may be disposed in the non-display area NDA of the main region MA. In this case, the display driver 200 may be disposed in the non-display area NDA of the main region MA, or may be disposed on the circuit board 300 connected to the display panel 100. By way of example, the display panel 100 may include the main region MA and the pad portion disposed in the non-display area NDA of the main region MA, and the circuit board 300 may be disposed on the pad portion and electrically connected to the pads PD of the pad portion.

The display driver 200 may output driving signals that drive the display panel 100. The display driver 200 may include a data driver. For example, the display driver 200 may supply data voltages to data lines electrically connected to the pixels PX.

In an embodiment, the display driver 200 may be formed as an integrated circuit (IC) and mounted on the display panel 100 by, for example, a chip on glass (COG) method, a chip on plastic (COP) method, or an ultrasonic method. However, embodiments are not limited thereto. For example, the display driver 200 may be disposed on the circuit board 300 by a chip on film (COF) method, and may be electrically connected to the display panel 100 through the pad portion.

In an embodiment, the display driver 200 may further include a power supply unit (also referred to as “power supply circuit”) that generates driving voltages utilized to drive the pixels PX, and may supply the driving voltages to power lines electrically connected to the pixels PX. In an embodiment, the power supply unit may be provided separately from the display driver 200, and may be electrically connected to the display panel 100 through the pad portion or the like. As an example, the power supply unit may be disposed on the circuit board 300 or on another circuit board electrically connected to the circuit board 300.

In an embodiment, the display driver 200 may further include a timing controller that outputs driving signals used to drive the gate driver GDR and the data driver, and may output the driving signals (for example, a gate control signal and a data control signal) that drive the gate driver GDR and the data driver to the gate driver GDR and the data driver. For example, the display driver 200 may supply gate control signals (for example, scan control signals, etc.) to the gate driver GDR through wires electrically connected to the gate driver GDR formed within the display panel 100. In an embodiment, the timing controller may be provided separately from the display driver 200 and electrically connected to the display panel 100 through the pad portion, or the like. As an example, the timing controller may be disposed on the circuit board 300 or on another circuit board electrically connected to the circuit board 300.

The circuit board 300 may be disposed on the pad portion of the display panel 100, and may be electrically connected to the display panel 100 through a conductive material (for example, anisotropic conductive film (ACF), etc.). As an example, the circuit board 300 may be attached to the pad portion of the display panel 100 using an anisotropic conductive film (ACF). In an embodiment, the circuit board 300 may be a flexible printed circuit board, a printed circuit board, or a flexible film such as a chip on film.

The touch driver 400 may be mounted on the circuit board 300. The touch driver 400 may be electrically connected to a touch sensing layer of the display panel 100. In an embodiment, the touch sensing layer of the display panel 100 may include touch electrodes constituting a capacitive touch sensor. In this case, the touch driver 400 may supply each touch drive signal to touch electrodes of the touch sensing layer, and may detect a touch input by sensing the amount of change in capacitance formed between the touch electrodes. In an embodiment, the touch driver 400 may be formed as an integrated circuit (IC).

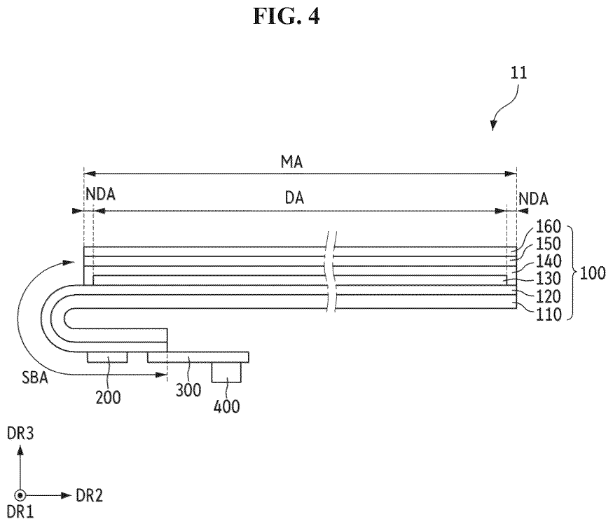

FIG. 4 is a cross-sectional view illustrating a display module according to an embodiment. For example, FIG. 4 schematically shows an example of a cross-section of the display module 11 in a state where the display panel 100 of FIGS. 2 and 3 is bent in the sub-region SBA.

Referring to FIGS. 2 to 4, the display panel 100 may include a substrate 110, a backplane layer 120, a light-emitting element layer 130, and an encapsulation layer 140 (or a protective layer). In an embodiment, the display panel 100 may further include a touch sensing layer 150 and an optical layer 160.

The substrate 110 may be a base substrate or a base member. The substrate 110 may be a flexible substrate which can be bent, folded or rolled, but is not limited thereto. In an embodiment, the substrate 110 may include a polymer resin such as polyimide (PI). In an embodiment, the substrate 110 may include a glass material or a metal material.

The backplane layer 120 may be disposed on the substrate 110. The backplane layer 120 may include circuit elements constituting pixel circuits of the pixels PX, for example, transistors and capacitors of the pixels PX.

The backplane layer 120 may further include wires. For example, the backplane layer 120 may include signal lines and power lines electrically connected to the sub-pixels SPX.

The signal lines of the backplane layer 120 may include gate lines and data lines that transmit gate signals and data voltages to the sub-pixels SPX, respectively. As an example, the gate lines may include scan lines and/or emission control lines that are electrically connected between the gate driver GDR and the sub-pixels SPX, and transmit scan signals and/or emission control signals to the sub-pixels SPX, respectively. The data lines may be electrically connected between the display driver 200 (for example, the data driver of the display driver 200) and the sub-pixels SPX, and transmit data voltages (or other types of data signals) to the sub-pixels SPX, respectively.

The power lines of the backplane layer 120 may include a plurality of power lines that transmit a plurality of driving voltages to the sub-pixels SPX. As an example, the power lines of the backplane layer 120 may include a first power line and a second power line that transmit a first driving voltage and a second driving voltage to the sub-pixels SPX, respectively. In an embodiment, the power lines of the backplane layer 120 may further include at least one of an initialization voltage line that transmits at least one initialization voltage to the sub-pixels SPX and a reference voltage line that transmits a reference voltage to the sub-pixels SPX. The type or number of the driving voltages supplied to the sub-pixels SPX may vary depending on the structure or driving method of the sub-pixels SPX.

In an embodiment, when the display panel 100 includes the gate driver GDR disposed in the non-display area NDA, the backplane layer 120 may further include circuit elements constituting the gate driver GDR, and wires (for example, signal lines and power lines that transmit gate control signals that drive the gate driver GDR and driving voltages of the gate driver GDR) electrically connected to the gate driver GDR.

The backplane layer 120 may be disposed in the display area DA, the non-display area NDA, and the sub-region SBA. The circuit elements constituting the pixel circuits of the pixels PX, and the signal lines and the power lines electrically connected to the pixels PX may be arranged in the display area DA of the backplane layer 120. The signal lines and the power lines of the display area DA may be extended to the non-display area NDA of the backplane layer 120, and each of the signal lines and the power lines may be electrically connected to the gate driver GDR, the display driver 200, the pad PD of the pad portion, or the like.

The light-emitting element layer 130 may be arranged on the backplane layer 120. The light-emitting element layer 130 may include light-emitting elements arranged in the emission areas of the pixels PX. The light-emitting element layer 130 may further include a structure (for example, a pixel defining film or bank) that defines or partitions the emission areas of the pixels PX.

The encapsulation layer 140 may be disposed on the light-emitting element layer 130. For example, the encapsulation layer 140 may cover the top surface and the side surface of the light-emitting element layer 130 and may protect the light-emitting element layer 130. In an embodiment, the encapsulation layer 140 may include at least one inorganic film and at least one organic film that encapsulate the light-emitting element layer 130. For example, the encapsulation layer 140 may include a plurality of inorganic encapsulation layers and an organic encapsulation layer interposed between the inorganic encapsulation layers.

The touch sensing layer 150 may be disposed on the encapsulation layer 140. For example, the touch sensing layer 150 may be disposed or formed on the encapsulation layer 140, or may be disposed on a separate substrate disposed on the encapsulation layer 140. The position of the touch sensing layer 150 is not limited thereto, and may vary according to embodiments. When the display module 11 (or the display device 1) does not provide a touch input function, the display module 11 may not include the touch sensing layer 150. In an embodiment, the touch sensing layer 150 may be provided separately from the display panel 100 and may be disposed on the display panel 100.

The touch sensing layer 150 may include elements that generate an electrical signal in response to a user's touch input. For example, the touch sensing layer 150 may include touch electrodes arranged in an area that provides the touch input function, and touch lines electrically connecting the touch electrodes to the touch driver 400. When the display module 11 provides the touch input function in the display area DA, the touch electrodes may be arranged in the display area DA. The touch lines may be connected to the touch electrodes in the main region MA (for example, the display area DA) where the touch electrodes are arranged. The touch lines may be extended to the sub-region SBA to be electrically connected to the plurality of pads PD arranged in the pad portion, and may be electrically connected to the touch driver 400 through the plurality of pads PD. A part of the touch lines arranged in the sub-region SBA may be disposed on the backplane layer 120 or inside the backplane layer 120.

The optical layer 160 may include an element that may adjust and/or improve the optical characteristics of the display panel 100. For example, the optical layer 160 may include at least one of a color filter layer (for example, a color filter layer including color filters corresponding to the emission wavelengths of the respective sub-pixels SPX), a polarizing layer, or an anti-reflection layer. The optical layer 160 may be provided integrally with the display panel 100, but is not limited thereto. The optical layer 160 may be omitted in an embodiment.

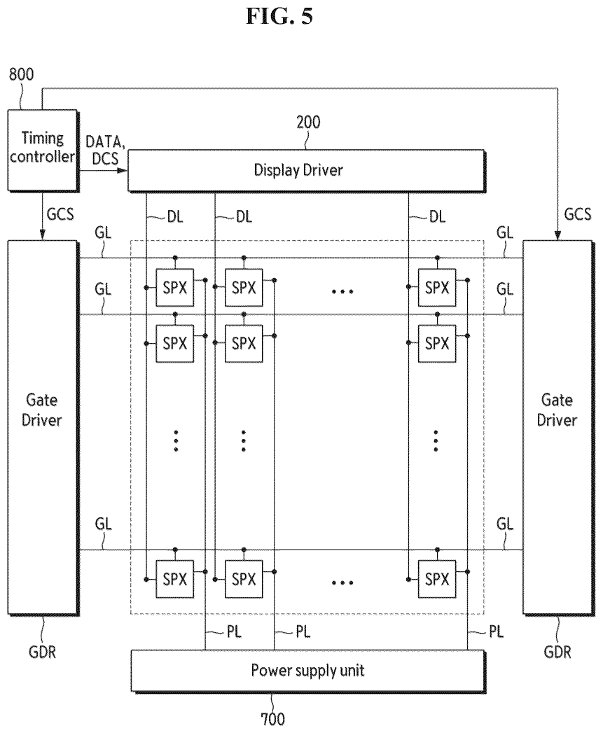

FIG. 5 is a block diagram illustrating a display device according to an embodiment. For example, FIG. 5 shows an example of components that may be included in the display device 1 of FIG. 1.

Referring to FIG. 5, the display device 1 according to an embodiment may include the sub-pixels SPX, the gate driver GDR, the display driver 200 (or a data driver), a power supply unit 700, and a timing controller 800. In FIG. 5, the display driver 200, the power supply unit 700, and the timing controller 800 are illustrated as separate components, but embodiments are not limited thereto. For example, the power supply unit 700 may be provided separately from the display driver 200, or may be integrated into a single integrated circuit together with the display driver 200. In addition, the timing controller 800 may be provided separately from the display driver 200, or may be integrated into a single integrated circuit together with the display driver 200.

The sub-pixels SPX may be electrically connected to respective gate lines GL, data lines DL and power lines PL. The sub-pixels SPX may be electrically connected to the gate driver GDR through the gate lines GL. The operation timing of the sub-pixels SPX may be controlled by respective gate signals applied from the gate driver GDR through the gate lines GL. The sub-pixels SPX may be electrically connected to the display driver 200 through the data lines DL. The sub-pixels SPX may emit light with a luminance corresponding to respective data voltages applied from the display driver 200 through the data lines DL. The sub-pixels SPX may be electrically connected to the power supply unit 700 through the power lines PL. The sub-pixels SPX may be driven by driving voltages applied from the power supply unit 700 through the power lines PL.

In FIG. 5, the sub-pixels SPX are illustrated as being connected to the gate driver GDR, the display driver 200, and the power supply unit 700 through the respective gate lines GL, data lines DL, and power lines PL, but embodiments are not limited thereto. For example, depending on the structure and/or operation method of the sub-pixel SPX, the sub-pixel SPX may be electrically connected to a single gate line GL or a plurality of gate lines GL, and may be operated by a single gate signal or a plurality of gate signals. In an embodiment, the sub-pixel SPX may be operated by a plurality of gate signals, and may be electrically connected to the gate driver GDR through the plurality of gate lines GL to transmit the respective gate signals. In addition, the sub-pixel SPX may be operated by a plurality of driving voltages, and may be electrically connected to the power supply unit 700 through the plurality of power lines PL to transmit the respective driving voltages.

The gate driver GDR and the display driver 200 may output driving signals that drive the sub-pixels SPX. For example, the gate driver GDR may output gate signals to the gate lines GL in response to a gate control signal GCS supplied from the timing controller 800. The display driver 200 may output data voltages to the data lines DL in response to image data DATA and a data control signal DCS supplied from the timing controller 800. For example, the display driver 200 may convert the image data DATA into analog data voltages and output them to the data lines DL.

The power supply unit 700 may output driving voltages that drive the sub-pixels SPX. For example, the power supply unit 700 may output a plurality of driving voltages including a first driving voltage and a second driving voltage of different potentials.

The timing controller 800 may receive the image data DATA and timing signals from the outside of the display module 11. The timing controller 800 may generate the gate control signal GCS and the data control signal DCS that control the display panel 100 in response to the timing signals. The timing controller 800 may output the gate control signal GCS and the data control signal DCS to the gate driver GDR and the display driver 200, respectively. In addition, the timing controller 800 may output the image data DATA to the display driver 200.

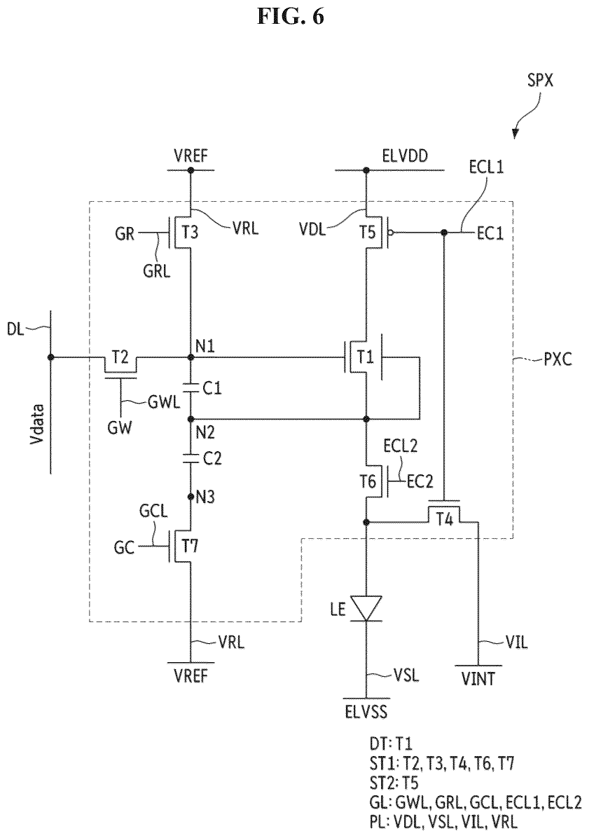

FIG. 6 is an equivalent circuit diagram illustrating a sub-pixel according to an embodiment. For example, FIG. 6 may be an equivalent circuit diagram showing one of the sub-pixels SPX of FIGS. 3 and 5. In an embodiment, the circuit configurations of the sub-pixels SPX constituting each pixel PX may be substantially the same.

Referring to FIG. 6 in addition to FIGS. 1 to 5, the sub-pixel SPX may be electrically connected to at least one gate driver GDR through at least one gate line GL. For example, the sub-pixel SPX may be electrically connected to the gate driver GDR via a plurality of gate lines GL. In an embodiment, the plurality of gate lines GL may include a write scan line GWL, a reset control line GRL, a gate control line GCL, a first emission control line ECL1, and a second emission control line ECL2. The gate driver GDR may output a write scan signal GW, a reset control signal GR, a gate control signal GC, a first emission control signal EC1, and a second emission control signal EC2 to the write scan line GWL, the reset control line GRL, the gate control line GCL, the first emission control line ECL1, and the second emission control line ECL2, respectively. The gate signals including the write scan signal GW, the reset control signal GR, the gate control signal GC, the first emission control signal EC1, and the second emission control signal EC2 may have pulses that are varied between a gate-on voltage and a gate-off voltage that can turn on or off each transistor that is turned on/off by each gate signal.

The sub-pixel SPX may be electrically connected to the power supply unit 700 through at least one power line PL. For example, the sub-pixel SPX may be electrically connected to the power supply unit 700 via the plurality of power lines PL and/or pads PD. In an embodiment, the plurality of power lines PL may include a first power line VDL (e.g., a first driving voltage line), a second power line VSL (e.g., a second driving voltage line), an initialization voltage line VIL (e.g., a third power line), and a reference voltage line VRL (e.g., a fourth power line). The power supply unit 700 may output a first driving voltage ELVDD (e.g., a high-potential pixel driving voltage or anode voltage), a second driving voltage ELVSS (e.g., a low-potential pixel driving voltage or cathode voltage), an initialization voltage VINT (e.g., an initialization voltage that initializes the voltage of a light-emitting element LE) and a reference voltage VREF (e.g., a reference voltage that initializes a pixel circuit PXC) to the first power line VDL, the second power line VSL, the initialization voltage line VIL and the reference voltage line VRL, respectively.

The sub-pixel SPX may be connected to the display driver 200 via the data line DL. The display driver 200 may output a data voltage Vdata corresponding to the image data DATA of each frame to the data line DL.

The sub-pixel SPX may include the pixel circuit PXC and the light-emitting element LE electrically connected to the pixel circuit PXC.

The pixel circuit PXC may control a driving current supplied to the light-emitting element LE in response to the driving signals supplied to the sub-pixel SPX (for example, the write scan signal GW, the reset control signal GR, the gate control signal GC, the first emission control signal EC1, the second emission control signal EC2, and the data voltage Vdata). The light emitting timing and the luminance of the light-emitting element LE may be controlled by the pixel circuit PXC.

The pixel circuit PXC may include a first transistor T1 (e.g., a driving transistor DT of the sub-pixel SPX) that controls a driving current flowing through the sub-pixel SPX and at least one switching transistor. In an embodiment, the pixel circuit PXC may include second to seventh transistors T2 to T7 as switching transistors. In addition, the pixel circuit PXC may further include at least one capacitor. As an example, the pixel circuit PXC may include a first capacitor C1 and a second capacitor C2. However, the structure or operation method of the pixel circuit PXC may be changed in various ways according to embodiments.

In an embodiment, the sub-pixel SPX may include heterogeneous transistors. For example, the sub-pixel SPX may include at least one P-type transistor and at least one N-type transistor. As an example, among the first to seventh transistors T1 to T7 constituting the pixel circuit PXC of the sub-pixel SPX, the fifth transistor T5 may be a P-type transistor, and the first, second, third, fourth, sixth and seventh transistors T1, T2, T3, T4, T6 and T7 may be N-type transistors. In an embodiment, among the first to seventh transistors T1 to T7 constituting the pixel circuit PXC of the sub-pixel SPX, the fifth and sixth transistors T5 and T6 may be P-type transistors, and the first, second, third, fourth and seventh transistors T1, T2, T3, T4 and T7 may be N-type transistors.

In an embodiment, the P-type transistor included in the sub-pixel SPX may be a P-type polycrystalline silicon transistor including an active layer including polycrystalline silicon (for example, low-temperature polycrystalline silicon (polycrystalline silicon formed in a low-temperature process)), and the N-type transistor included in the sub-pixel SPX may be an N-type oxide transistor including an active layer including an oxide semiconductor. In an embodiment, the active layer of the P-type transistor (for example, the active layer including polycrystalline silicon) and the active layer of the N-type transistor (for example, the active layer including an oxide semiconductor) may be arranged in different layers within the display panel 100.

In describing embodiments herein, the first transistor T1 may also be referred to as “driving transistor DT.” Among the switching transistors (for example, the second to seventh transistors T2 to T7), at least one switching transistor including the same type of semiconductor material (for example, an oxide semiconductor) as the first transistor T1, for example, each of the second, third, fourth, sixth, and seventh transistors T2, T3, T4, T6 and T7, may also be referred to as “first switching transistor ST1.” The active layers of the first transistor T1 and the first switching transistors ST1 may be formed simultaneously. Among the switching transistors, at least one switching transistor including a different type of semiconductor material (for example, polycrystalline silicon) from the first transistor T1, for example, the fifth transistor T5 may also be referred to as a “second switching transistor ST2.”

The first transistor T1 may be electrically connected between the fifth transistor T5 and the sixth transistor T6. The first transistor T1 may be electrically connected to the first power line VDL via the fifth transistor T5, and may be electrically connected to the light-emitting element LE via the sixth transistor T6. The gate electrode of the first transistor T1 may be connected to a first node N1. The first transistor T1 may control the driving current flowing through the sub-pixel SPX according to the voltage of the first node N1 (for example, a voltage corresponding to the data voltage Vdata).

The second transistor T2 may be electrically connected between the data line DL and the first node N1. The gate electrode of the second transistor T2 may be electrically connected to the write scan line GWL. The second transistor T2 may be turned on by the write scan signal GW of a gate-on voltage (for example, a high-level voltage at which the second transistor T2 can be turned on) supplied from the write scan line GWL. When the second transistor T2 is turned on, the data voltage Vdata of the data line DL may be transmitted to the first node N1.

When the voltage difference between the gate electrode and the source electrode of the first transistor T1 becomes about equal to or higher than the threshold voltage of the first transistor T1 due to the data voltage Vdata applied to the first node N1, the first transistor T1 may be turned on. When the first transistor T1 is turned on, a driving current corresponding to the data voltage Vdata may flow through the first transistor T1.

The third transistor T3 may be electrically connected between the reference voltage line VRL and the first node N1. The gate electrode of the third transistor T3 may be electrically connected to the reset control line GRL. The third transistor T3 may be turned on by the reset control signal GR of a gate-on voltage (for example, a high-level voltage at which the third transistor T3 can be turned on) supplied from the reset control line GRL. When the third transistor T3 is turned on, the potential of the first node N1 may be initialized to the reference voltage VREF of the reference voltage line VRL.

The fourth transistor T4 may be electrically connected between the light-emitting element LE and the initialization voltage line VIL. The gate electrode of the fourth transistor T4 may be electrically connected to the first emission control line ECL1. The fourth transistor T4 may be turned on by the first emission control signal EC1 of a gate-on voltage (for example, a high-level voltage at which the fourth transistor T4 can be turned on) supplied from the first emission control line ECL1. When the fourth transistor T4 is turned on, the potential of the anode electrode of the light-emitting element LE may be initialized to the initialization voltage VINT of the initialization voltage line VIL.

The fifth transistor T5 may be electrically connected between the first power line VDL and the first transistor T1 (for example, between the first power line VDL and the drain electrode of the first transistor T1). The gate electrode of the fifth transistor T5 may be electrically connected to the first emission control line ECL1. The fifth transistor T5 may be turned on by the first emission control signal EC1 of a gate-on voltage (for example, a low-level voltage at which the fifth transistor T5 can be turned on) supplied from the first emission control line ECL1. When the fifth transistor T5 is turned on, the first transistor T1 may be electrically connected to the first power line VDL.

The sixth transistor T6 may be electrically connected between the first transistor T1 and the light-emitting element LE (for example, between the source electrode of the first transistor T1 and the anode electrode of the light-emitting element LE). The gate electrode of the sixth transistor T6 may be electrically connected to the second emission control line ECL2. The sixth transistor T6 may be turned on by the second emission control signal EC2 of a gate-on voltage (for example, a high-level voltage at which the sixth transistor T6 can be turned on) supplied from the second emission control line ECL2. When the sixth transistor T6 is turned on, the first transistor T1 may be electrically connected to the light-emitting element LE.

When the fifth transistor T5 and the sixth transistor T6 are turned on, the first transistor T1 and the light-emitting element LE may be connected in series between the first power line VDL and the second power line VSL. Accordingly, the driving current corresponding to the data voltage Vdata may flow through the light-emitting element LE, and the light-emitting element LE may emit light with a luminance corresponding to the driving current. Accordingly, the sub-pixel SPX may emit light with a luminance corresponding to the data voltage Vdata during an emission period in which the fifth transistor T5 and the sixth transistor T6 are turned on.

The seventh transistor T7 may be electrically connected between the reference voltage line VRL and a third node N3. The gate electrode of the seventh transistor T7 may be electrically connected to the gate control line GCL. The seventh transistor T7 may be turned on by the gate control signal GC of a gate-on voltage (for example, a high-level voltage at which the seventh transistor T7 can be turned on) supplied from the gate control line GCL. When the seventh transistor T7 is turned on, the potential of the third node N3 may be initialized to the reference voltage VREF of the reference voltage line VRL.

The first capacitor C1 may be electrically connected between the first node N1 and a second node N2. The first capacitor C1 may be charged with the data voltage Vdata applied to the first node N1. Due to the voltage charged in the first capacitor C1, the first transistor T1 may be stably turned on during an emission period of the sub-pixel SPX.

The second capacitor C2 may be electrically connected between the second node N2 and the third node N3. The voltage of the first capacitor C1 corresponds to the potential difference between the first node N1 and the second node N2, is varied by the data voltage Vdata, and may be divided by the second capacitor C2.

The light-emitting element LE may be electrically connected between the pixel circuit PXC and the second power line VSL. For example, the anode electrode of the light-emitting element LE may be connected to a node between the sixth transistor T6 and the fourth transistor T4, and the cathode electrode of the light-emitting element LE may be connected to the second power line VSL. The light-emitting element LE may emit light to correspond to the driving current supplied from the pixel circuit PXC.

In an embodiment, the light-emitting element LE may be an organic light-emitting diode (OLED) including an organic light-emitting layer, but is not limited thereto. For example, the light-emitting element LE may be another type of light-emitting element, such as a quantum dot light-emitting diode (quantum dot LED) including a quantum dot light-emitting layer, an inorganic light-emitting diode (inorganic LED) including an inorganic semiconductor, a micro light-emitting diode (micro LED), or a nano light-emitting diode (nano LED).

In the sub-pixel SPX according to an embodiment, the first transistor T1 may be a dual-gate transistor further including a sub-gate electrode. As an example, the first transistor T1 may include an active layer including a channel region, a gate electrode connected to the first node N1 (also referred to as “main gate electrode” or “first gate electrode”), and a sub-gate electrode (also referred to as “second gate electrode”) facing the main gate electrode while the channel region of the active layer is interposed between the sub-gate electrode and the main gate electrode. In an embodiment, the gate electrode of the first transistor T1 may be a top-gate electrode disposed on the active layer, and the sub-gate electrode of the first transistor T1 may be a bottom-gate electrode disposed below the active layer.

In an embodiment, the sub-gate electrode of the first transistor T1 may be utilized to adjust the characteristics of the first transistor T1. For example, when the first transistor T1 is formed as an oxide transistor including an oxide semiconductor, the rate of change in a source-drain current (a driving current flowing between the source electrode and the drain electrode of the first transistor T1) of the first transistor T1 according to a gate-source voltage (a voltage between the gate electrode and the source electrode of the first transistor T1) of the first transistor T1 may be relatively high, as compared to the case where the first transistor T1 is formed as a transistor including low-temperature polycrystalline silicon. Accordingly, it may be difficult to finely or accurately adjust the driving current by the first transistor T1 in a low-grayscale region, which may cause uneven image quality, such as a visible spot in an image.

In an embodiment, the sub-gate electrode of the first transistor T1 is formed under the active layer of the first transistor T1, and the characteristics of the source-drain current of the first transistor T1 according to the gate-source voltage of the first transistor T1 may be appropriately adjusted by using this sub-gate electrode, which may improve the above issue. For example, by connecting the sub-gate electrode of the first transistor T1 to the source electrode of the first transistor T1, the subthreshold slope of the first transistor T1 may be adjusted and the sensitivity of the current-voltage change of the first transistor T1 may be reduced. By way of example, when the sub-gate electrode of the first transistor T1 is connected to the source electrode of the first transistor T1, the slope of the current curve representing the relationship between the gate-source voltage and the source-drain current of the first transistor T1 becomes gentle, and the driving voltage range of the first transistor T1 may be widened. Accordingly, the driving current flowing through the sub-pixel SPX may be controlled more easily and/or precisely, and the image quality of the display device 1 may be improved.

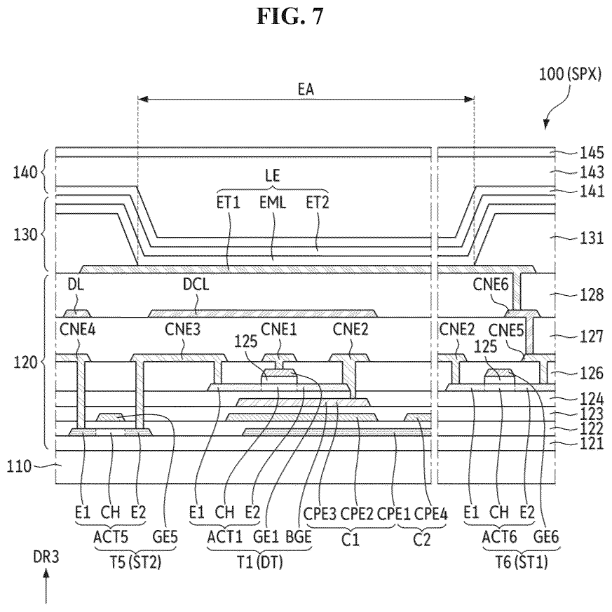

Still referring to FIG. 6, in an embodiment, the sub-gate electrode of the first transistor T1 may be formed by the third capacitor electrode CPE3 (see FIG. 7), which is positioned below the active layer ACT1 (see FIG. 7) and overlaps the channel region CH (see FIG. 7 of the first transistor T1. The first gate electrode GE1 may be disposed above the active layer ACT1 with the channel region CH interposed between the first gate electrode GE1 and the third capacitor electrode CPE3. This vertical stack may enable the first transistor T1 to function as a dual-gate transistor, with the third capacitor electrode CPE3 serving as a sub-gate electrode.

The third capacitor electrode CPE3 may also serve as an upper electrode of the first capacitor C1, and may be electrically connected to the first capacitor electrode CPE1. In this configuration, the third capacitor electrode CPE3 may perform a dual function, including acting as a sub-gate electrode for the first transistor T1 and contributing to the capacitance of the first capacitor C1. Because the third capacitor electrode CPE3 is also electrically connected to the source electrode of the first transistor T1, the sub-gate potential may track source voltage fluctuations, which may allow the subthreshold characteristics of the first transistor T1 to be modulated dynamically.

The above structure may enable fine-tuned control over the source-drain current of the first transistor T1, which may be beneficial in low-luminance driving conditions involving precise current modulation. In addition, because the first capacitor C1 and the dual-gate first transistor T1 are vertically stacked, the layout footprint of the sub-pixel SPX can be reduced. This vertical integration may allow for higher aperture ratios and improved resolution without sacrificing electrical performance or image quality.

FIG. 7 is a cross-sectional view illustrating a display panel according to an embodiment. For example, FIG. 7 schematically shows a cross-section of the display panel 100 for a portion of the display area DA including a portion of a single sub-pixel SPX.

Referring to FIGS. 1 to 7, the display panel 100 may include the substrate 110, and the backplane layer 120, the light-emitting element layer 130, and the encapsulation layer 140, which are disposed on the substrate 110. In an embodiment, the display panel 100 may include at least one of the touch sensing layer 150 or the optical layer 160 of FIG. 3.

The substrate 110 may be a base member used to form the display panel 100, and may include a single layer or multiple layers. In an embodiment, the substrate 110 may include a flexible material such as polymer resin and may be a flexible substrate capable of transformation such as, for example, bending, folding, or rolling. However, embodiments are not limited thereto. In an embodiment, the substrate 110 may be a rigid substrate including a hard material such as glass.

The substrate 110 may include the display area DA and the non-display area NDA. The display area DA may include pixel areas where the pixels PX are arranged. Each pixel area may include pixel circuit areas in which the circuit elements included in the pixel circuits PXC of the sub-pixels SPX are arranged and emission areas EA in which the light-emitting elements LE of the sub-pixels SPX are arranged.

In an embodiment, the pixel circuit area and the emission area EA of each sub-pixel SPX may overlap in the third direction DR3. For example, the light-emitting element LE of each sub-pixel SPX may be disposed above the circuit elements included in the pixel circuit PXC of each sub-pixel SPX. If the pixel circuit PXC and the light-emitting element LE of each sub-pixel SPX can be electrically connected to each other, the mutual arrangement structure between the pixel circuit area and the emission area EA is not limited thereto.

The backplane layer 120 may include the circuit elements included in the pixel circuits PXC of the sub-pixels SPX and wires electrically connected to the sub-pixels SPX. For example, the backplane layer 120 may include the first to seventh transistors T1 to T7 of FIG. 6, the first capacitor C1, the second capacitor C2, the gate lines GL, the data line DL, and the power lines PL.

FIG. 7 illustrates the first transistor T1, the fifth transistor T5, the sixth transistor T6, the first capacitor C1, and the second capacitor C2 included in a single pixel circuit PXC, as one example of the circuit elements that may be included in the backplane layer 120. The fifth transistor T5 may be a second switching transistor ST2 that includes a semiconductor material different from the semiconductor material included in the first transistor T1 and is formed in a different process from the first transistor T1 (e.g., formed prior to the first transistor T1). The sixth transistor T6 may be one of the first switching transistors ST1 including the same semiconductor material as the first transistor T1 and formed simultaneously with the first transistor T1.

For example, as illustrated in FIG. 7, in an embodiment, the relative arrangement of the first transistor T1, the fifth transistor T5, and the sixth transistor T6 within the backplane layer 120 may enable efficient vertical integration of circuit elements, which may contribute to improved area utilization of the pixel circuit PXC. For example, the simultaneous formation of the sixth transistor T6 with the first transistor T1 in an embodiment may allow these transistors to be fabricated using a common oxide semiconductor process, which may reduce mask steps and achieve alignment precision between the overlapping structures. In contrast, the fifth transistor T5, formed earlier and using a different semiconductor material such as polycrystalline silicon, may serve as a control switch that selectively couples the driving voltage from the first power line VDL to the drain of the first transistor T1. This difference in process timing and material selection between the first transistor T1 and the fifth transistor T5 may facilitate vertical stacking of transistors having different functions and electrical characteristics, supporting the integration of a stacked capacitor structure while maintaining a compact circuit footprint.

Additionally, FIG. 7 shows the data line DL and a constant voltage line DCL disposed above the circuit elements, as one example of the wires that may be included in the backplane layer 120. In an embodiment, the data line DL of FIG. 7 may be the data line DL electrically connected to the sub-pixel SPX of FIG. 7 (e.g., the data line DL electrically connected to the second transistor T2 of FIG. 6), and the constant voltage line DCL may be any one (e.g., the first power line VDL) of the power lines PL electrically connected to the sub-pixel SPX of FIG. 7. FIG. 7 shows an embodiment in which the data line DL and the constant voltage line DCL are disposed on a sixth insulating layer 127 covering the transistors of the pixel circuit PXC, but embodiments are not limited thereto. For example, each of the wires of the backplane layer 120 may include a single-layer or multi-layer conductive pattern included in at least one conductive layer included in the backplane layer 120, and the position or structure of each of the wires may be variously changed depending on embodiments.

The backplane layer 120 of the display panel 100 may include at least one semiconductor layer, a plurality of conductive layers, and a plurality of insulating layers. In an embodiment, when the circuit elements of the backplane layer 120 include at least two types of transistors including different semiconductor materials, the backplane layer 120 may include a plurality of semiconductor layers. In an embodiment, the plurality of semiconductor layers may include a polycrystalline silicon semiconductor layer (also referred to as “first semiconductor layer”) including first semiconductor patterns including polycrystalline silicon (e.g., low-temperature polycrystalline silicon), and an oxide semiconductor layer (also referred to as “second semiconductor layer”) including second semiconductor patterns including an oxide semiconductor.

For example, a buffer layer 121 may be disposed on the substrate 110. The buffer layer 121 may include a material (e.g., silicon nitride (SiNx), silicon oxide (SiOx), silicon oxynitride (SiON), titanium oxide (TiOx), aluminum oxide (AlOx), or other inorganic insulating materials) suitable for protecting the circuit elements of the backplane layer 120 and the light-emitting elements LE on the backplane layer 120 from moisture permeating through the substrate 110 that is susceptible to moisture permeation. The buffer layer 121 may be formed as a single layer or multiple layers.

In an embodiment, the backplane layer 120 may further include a lower conductive layer disposed between the substrate 110 and the buffer layer 121. The lower conductive layer may include at least one conductive pattern, a light blocking layer, and/or the like. For example, after forming at least one conductive pattern and/or the light blocking layer on the substrate 110, the buffer layer 121 may be formed on the conductive pattern and/or the light blocking layer.

In describing embodiments, a conductive pattern may mean a pattern having conductivity. For example, a conductive pattern may collectively refer to a wire, an electrode included in at least one circuit element, a connection electrode or a bridge pattern electrically connected to the at least one circuit element or the wire, and/or a part thereof.

The first semiconductor patterns (e.g., patterns of the first semiconductor layer) including a first semiconductor material may be disposed on the buffer layer 121. For example, a polycrystalline silicon semiconductor layer including the first semiconductor patterns including polycrystalline silicon (e.g., low-temperature polycrystalline silicon) may be disposed on the buffer layer 121.

In an embodiment, the first semiconductor patterns may include the active layers of the second switching transistors ST2 included in the sub-pixels SPX. In an embodiment, the first semiconductor patterns may include an active layer ACT5 of the fifth transistor T5 included in each of the sub-pixels SPX. The active layer ACT5 of the fifth transistor T5 may also be referred to as “fifth active layer ACT5.” The fifth active layer ACT5 may include a channel region CH overlapping a gate electrode GE5 of the fifth transistor T5, and a first electrode region E1 and a second electrode region E2 disposed on different sides of the channel region CH. One of the first electrode region E1 and the second electrode region E2 of the fifth active layer ACT5 may be a source region (or source electrode), and the other may be a drain region (or drain electrode).

In an embodiment according to the above configuration, the use of polycrystalline silicon for the fifth active layer ACT5 may allow the fifth transistor T5 to be formed in an earlier process step than the later-formed driving transistor T1 and first capacitor C1, which may be formed in subsequent layers using a different semiconductor material. This sequencing may enable a vertically stacked arrangement of multiple transistors and capacitive elements within each sub-pixel SPX. Such vertical integration may help conserve layout area and facilitate the inclusion of a high-capacitance first capacitor C1 without expanding the overall pixel circuit footprint. By allocating the fifth transistor T5 to the lower-level semiconductor pattern, the circuit architecture may maintain electrical independence between process modules while improving three-dimensional integration within the backplane layer 120.

In an embodiment, the first electrode region E1 and the second electrode region E2 of the fifth active layer ACT5 may become conductive by a doping process. Accordingly, the first electrode region E1 and the second electrode region E2 of the fifth active layer ACT5 may include the first semiconductor material and a conductive dopant doped into the first semiconductor material. The channel region CH of the fifth active layer ACT5 may be a portion that maintains semiconductor properties, and may be masked by the gate electrode GE5 of the fifth transistor T5 or a separate mask during the doping process to form the first electrode region E1 and the second electrode region E2 in the fifth active layer ACT5. The gate electrode GE5 of the fifth transistor T5 may also be referred to as “fifth gate electrode GE5.” In an embodiment, the doping process for forming the first electrode region E1 and the second electrode region E2 in the fifth active layer ACT5 may be performed after forming the conductive patterns of a first conductive layer including the fifth gate electrode GE5. However, embodiments are not limited thereto, and other methods and/or materials may be used to increase the conductivity of the first electrode region E1 and the second electrode region E2 included in each of the active layers of the first semiconductor patterns.

In an embodiment, the doping of the first and second electrode regions E1 and E2 in the fifth active layer ACT5 may enable the fifth transistor T5 to function reliably as a current path switch to the first transistor T1. Because the doping process occurs after the formation of the fifth gate electrode GE5, the channel region CH beneath the gate can be defined with high alignment precision, resulting in stable threshold voltage characteristics. In addition, forming this transistor within the first semiconductor layer, prior to the formation of the second semiconductor layer for the first transistor T1, may support the improved vertical stacking configuration of the pixel circuit PXC. This layer-separated configuration may contribute to reduced layout area and improved integration of the dual-gate transistor and high-capacitance storage structure in the upper semiconductor layer.

According to an embodiment, by forming at least one of the transistors included in the sub-pixels SPX using polycrystalline silicon, the power consumption of the display device 1 may be reduced or improved.

In an embodiment, at least some of driver transistors formed in the non-display area NDA of the display panel 100 may be further formed using the first semiconductor material. For example, by using polycrystalline silicon (e.g., low-temperature polycrystalline silicon), the fifth transistors T5 of the display area DA may be formed while simultaneously forming the driver transistors of the gate driver GDR. When the driver transistors of the non-display area NDA are formed using polycrystalline silicon, the integration density of the driver transistors may be increased and the non-display area NDA may be reduced or minimized.

In an embodiment, by forming the fifth transistors T5 in the display area DA and the driver transistors in the non-display area NDA from the same polycrystalline silicon layer, the fabrication process may be simplified, and the number of photolithography steps may be reduced. This unified process may also facilitate improved alignment between circuit elements in the display and non-display area DA and NDA, which can contribute to improving signal timing and reducing parasitic effects. In addition, because the driver transistors in the non-display area NDA can be made smaller and denser using polycrystalline silicon, the overall non-display area can be reduced, enabling narrower bezels and contributing to a higher screen-to-body ratio.

The first semiconductor patterns may further include at least one capacitor electrode included in each of the sub-pixels SPX. For example, the first semiconductor patterns may further include a first capacitor electrode CPE1 constituting at least one capacitor in each of the sub-pixels SPX.

The first capacitor electrode CPE1 may include the first semiconductor material (e.g., polycrystalline silicon or low-temperature polycrystalline silicon) used in the formation of the fifth active layer ACT5, and a conductive dopant doped into the first semiconductor material. Accordingly, the first capacitor electrode CPE1 may substantially function as a conductive pattern and may form at least one capacitor together with at least another capacitor electrode overlapping the first capacitor electrode CPE1.

In an embodiment, the doping process for forming the first capacitor electrode CPE1 may be performed before other conductive patterns are formed on a first insulating layer 122 covering the first capacitor electrode CPE1. In an embodiment, after forming the first insulating layer 122 covering the first semiconductor patterns, a mask covering the fifth active layer ACT5 may be disposed on the first insulating layer 122 to mask the fifth active layer ACT5. In this state, the first semiconductor patterns, not covered by the mask, may be uniformly doped. Accordingly, the first capacitor electrode CPE1 including the first semiconductor material may be formed in a pattern having appropriate conductivity.

For example, in an embodiment, by forming the first capacitor electrode CPE1 from the same semiconductor layer as the fifth active layer ACT5, the layout density of the sub-pixel SPX can be improved, and capacitor area can be more effectively utilized within the limited pixel footprint. In addition, the ability to simultaneously dope and pattern both transistor active regions and capacitor electrodes during the same process step may result in a simplified manufacturing sequence and reduced process variation. This vertical integration may support a more compact and uniform backplane structure, contributing to stable electrical performance and reduced parasitic interference.

In an embodiment, a second capacitor electrode CPE2 and a third capacitor electrode CPE3 may be sequentially disposed on the first capacitor electrode CPE1. The first capacitor electrode CPE1, the second capacitor electrode CPE2, and the third capacitor electrode CPE3 may overlap each other in the thickness direction (e.g., the third direction DR3) of the substrate 110. The first capacitor electrode CPE1 and the third capacitor electrode CPE3 may be electrically connected to each other. The second capacitor electrode CPE2 may be disposed between the first capacitor electrode CPE1 and the third capacitor electrode CPE3. The first insulating layer 122 and a second insulating layer 123 may be disposed between the first capacitor electrode CPE1 and the second capacitor electrode CPE2, and between the second capacitor electrode CPE2 and the third capacitor electrode CPE3, respectively.

The first capacitor C1 may be formed by the first capacitor electrode CPE1, the second capacitor electrode CPE2, and the third capacitor electrode CPE3. For example, a capacitance may be formed between the first capacitor electrode CPE1 and the second capacitor electrode CPE2, and between the second capacitor electrode CPE2 and the third capacitor electrode CPE3, and the first capacitor C1 may be formed by the capacitance. In an embodiment, the first capacitor electrode CPE1 and the third capacitor electrode CPE3 may be electrically connected to the second node N2 illustrated in FIG. 6 to form one electrode of the first capacitor C1, and the second capacitor electrode CPE2 may be electrically connected to the first node N1 of FIG. 6 to form the other electrode of the first capacitor C1. The capacitance formed between the first capacitor electrode CPE1 and the second capacitor electrode CPE2, and the capacitance formed between the second capacitor electrode CPE2 and the third capacitor electrode CPE3, may be formed in a manner where they are connected in parallel in the circuit. Accordingly, the capacity of the first capacitor C1 may be appropriately secured while reducing or minimizing the formation area of the first capacitor C1.

In an embodiment, the first capacitor electrode CPE1 may further form one electrode of the second capacitor C2. For example, the first capacitor electrode CPE1 may extend outside a region where the second capacitor electrode CPE2 is formed and may overlap a fourth capacitor electrode CPE4. The first capacitor electrode CPE1 and the fourth capacitor electrode CPE4 may overlap each other in the thickness direction (e.g., the third direction DR3) of the substrate 110. The first insulating layer 122 may be disposed between the first capacitor electrode CPE1 and the fourth capacitor electrode CPE4.

The second capacitor C2 may be formed by the first capacitor electrode CPE1 and the fourth capacitor electrode CPE4. For example, a capacitance may be formed between the first capacitor electrode CPE1 and the fourth capacitor electrode CPE4, and the second capacitor C2 may be formed by the capacitance. In an embodiment, the first capacitor electrode CPE1 may be electrically connected to the second node N2 of FIG. 6 to form one electrode of the second capacitor C2, and the fourth capacitor electrode CPE4 may be electrically connected to the third node N3 of FIG. 6 to form the other electrode of the second capacitor C2. According to the above-described embodiment, the first capacitor C1 and the second capacitor C2 may be easily or appropriately formed by using the first capacitor electrode CPE1.

Thus, in an embodiment, by configuring the first capacitor electrode CPE1 as a common electrode shared between the first capacitor C1 and the second capacitor C2, the sub-pixel circuit layout may be improved to reduce the overall footprint occupied by capacitor structures. This shared electrode configuration may allow for vertical stacking of capacitive layers while avoiding duplication of conductive regions, which may conserve backplane area. As a result, the pixel circuit PXC can achieve both high capacitance density and compact layout efficiency, which may be applicable in high-resolution displays where sub-pixel area is limited. In addition, the stacked structure may provide improved capacitive coupling stability due to the shielding effect of the second capacitor electrode CPE2 and the symmetric layering of insulating films.

The first insulating layer 122 may be disposed on the first semiconductor patterns including the fifth active layer ACT5 and the first capacitor electrode CPE1. The first insulating layer 122 may include at least one insulating material (e.g., an inorganic insulating material) and may be formed as a single layer or multiple layers.

First conductive patterns (e.g., first gate patterns of the first conductive layer) including a conductive material may be disposed on the first insulating layer 122. The first conductive patterns may include the gate electrodes of the second switching transistors ST2 included in the sub-pixels SPX. In an embodiment, the first conductive patterns may include the fifth gate electrode GE5 of each of the sub-pixels SPX.

In an embodiment, the first conductive patterns may further include the gate electrodes included in the driver transistors of the gate driver GDR. In an embodiment, the driver transistors of the gate driver GDR and the fifth transistors T5 of the sub-pixels SPX may be simultaneously formed using the same material.

The first conductive patterns may further include at least one capacitor electrode included in each of the sub-pixels SPX. For example, the first conductive patterns may further include the second capacitor electrode CPE2 forming the first capacitor C1, and the fourth capacitor electrode CPE4 forming the second capacitor C2. The second capacitor electrode CPE2 and the fourth capacitor electrode CPE4 may be spaced apart from each other in each sub-pixel area.

For example, in an embodiment, forming the second capacitor electrode CPE2 and the fourth capacitor electrode CPE4 as part of the first conductive patterns may improve integration density and streamline fabrication. For example, by forming these capacitor electrodes simultaneously with the gate electrodes of the second switching transistors ST2 and the driver transistors of the gate driver GDR, the number of photolithography steps may be reduced, thereby lowering manufacturing complexity and improving alignment accuracy between transistor gates and associated capacitor structures. This simultaneous formation may also improve electrical consistency across the sub-pixels SPX, which may lead to improved reliability and uniformity in pixel operation.

The second insulating layer 123 may be disposed on the first conductive patterns. The second insulating layer 123 may include at least one insulating material (e.g., an inorganic insulating material) and may be formed as a single layer or multiple layers.

Second conductive patterns (e.g., second gate patterns of the second conductive layer) including a conductive material may be disposed on the second insulating layer 123. The second conductive patterns may include a sub-gate electrode BGE of the first transistor T1 and the third capacitor electrode CPE3 of the first capacitor C1 included in each of the sub-pixels SPX. In an embodiment, the sub-gate electrode BGE of the first transistor T1 and the third capacitor electrode CPE3 in each sub-pixel SPX may be integrally formed. In an embodiment, the sub-gate electrode BGE of the first transistor T1 and the third capacitor electrode CPE3 in each sub-pixel SPX may be formed in substantially one conductive pattern.

The sub-gate electrode BGE of the first transistor T1 may face the channel region CH of the first transistor T1 and the gate electrode GE1 of the first transistor T1. For example, the sub-gate electrode BGE of the first transistor T1 may face the gate electrode GE1 of the first transistor T1, while the active layer ACT1 of the first transistor T1 is interposed between the sub-gate electrode BGE and the gate electrode GE1. The active layer ACT1 of the first transistor T1 may also be referred to as “first active layer ACT1,” and the gate electrode GE1 of the first transistor T1 may also be referred to as “first gate electrode GE1.” The sub-gate electrode BGE of the first transistor T1 may be electrically connected to the second electrode region E2 (e.g., a source region or a source electrode) of the first transistor T1. In an embodiment, the sub-gate electrode BGE of the first transistor T1 may be electrically connected to the second electrode region E2 of the first transistor T1 through a second connection electrode CNE2.

The sub-gate electrode BGE of the first transistor T1 may be utilized to adjust the characteristics of the first transistor T1. For example, by adjusting the thickness of the third insulating layer 124 disposed between the first active layer ACT1 and the sub-gate electrode BGE of the first transistor T1, the characteristics of the first transistor T1 may be adjusted in a targeted direction or shape. In an embodiment, the thickness of the third insulating layer 124 may be appropriately adjusted or reduced to adjust the subthreshold slope of the first transistor T1 to a targeted shape or range and to reduce the sensitivity of the current-voltage variation of the first transistor T1.

For example, in an embodiment, the sub-gate electrode BGE and the third capacitor electrode CPE3 may be formed from a common conductive pattern, which may enable efficient utilization of the second conductive layer. This dual-purpose structure may reduce the total number of patterning steps while simultaneously achieving alignment between the sub-gate of the first transistor T1 and one of the electrodes of the first capacitor C1. The integration of the sub-gate electrode BGE and the third capacitor electrode CPE3 may also improve electrical consistency by maintaining uniform film thickness and material properties across the upper portions of the sub-pixel SPX, which may contribute to both stable subthreshold behavior of the first transistor T1 and reliable capacitance characteristics of the first capacitor C1.

In an embodiment, by forming the first capacitor C1 by the first capacitor electrode CPE1, the second capacitor electrode CPE2, and the third capacitor electrode CPE3 that overlap each other, a suitable capacitance for the first capacitor C1 may be easily or appropriately secured. Accordingly, the formation area of the first capacitor C1 may be reduced or minimized. For example, the third capacitor electrode CPE3 may be formed in a limited area so as not to overlap other circuit elements or wires around the first transistor T1 while overlapping the first transistor T1. Therefore, even if the thickness of the third insulating layer 124 is reduced, signal interference due to the coupling effect between the third capacitor electrode CPE3 and other circuit elements or wires in the vicinity may be prevented or reduced, and the operating characteristics of the sub-pixel SPX may be stabilized.

In addition, in an embodiment, by configuring the third capacitor electrode CPE3 to overlap the first transistor T1 while avoiding other surrounding circuit elements, the stacked capacitor structure can be implemented in a layout-efficient manner that may preserve routing space for additional signal lines or driving elements. This overlap may not only reduce area consumption, but also may enable high capacitance density directly adjacent to the driving transistor. As a result, the capacitor can store sufficient charge for stable low-current operation, while the reduced thickness of the third insulating layer 124 may improve capacitive coupling, and the risk of unintended capacitive interference may be mitigated by restricting the spread of the third capacitor electrode CPE3. As a result, embodiments may support precise control of the sub-pixel SPX's threshold and drive characteristics.

The third insulating layer 124 may be disposed on the second conductive patterns. The third insulating layer 124 may include at least one insulating material (e.g., an inorganic insulating material) and may be formed as a single layer or multiple layers.

The second semiconductor patterns (e.g., patterns of the second semiconductor layer) including the second semiconductor material may be disposed on the third insulating layer 124. In an embodiment, the second semiconductor material may include at least one of zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO), or indium-tin-gallium-zinc oxide (ITGZO), or another oxide semiconductor.

The second semiconductor patterns may include the first active layers ACT1 of the first transistors T1 and the active layers of the first switching transistors ST1 included in the sub-pixels SPX. In an embodiment, the second semiconductor patterns may include the first active layer ACT1 of the first transistor T1 and an active layer ACT6 of the sixth transistor T6 included in each of the sub-pixels SPX. The active layer ACT6 of the sixth transistor T6 may also be referred to as “sixth active layer ACT6.” As shown in FIG. 6, when the first switching transistors ST1 of each of the sub-pixels SPX include the second, third, fourth, sixth, and seventh transistors T2, T3, T4, T6, and T7, the second semiconductor patterns may further include the active layers of the second, third, fourth, and seventh transistors T2, T3, T4, and T7 in addition to the first active layer ACT1 and the sixth active layer ACT6.

Each active layer included in the second semiconductor patterns may include the channel region CH overlapping the gate electrode of each transistor, and the first electrode region E1 and the second electrode region E2 disposed on different sides of the channel region CH. One of the first electrode region E1 and the second electrode region E2 of each transistor may be a source region (or source electrode), and the other may be a drain region (or drain electrode).

In an embodiment, the first electrode region E1 and the second electrode region E2 included in each active layer of the second semiconductor patterns may be made conductive to have higher conductivity than the channel region CH in a process of forming a fourth insulating layer 125 and/or a fifth insulating layer 126 on the second semiconductor patterns, and in a post-treatment process or the like. For example, in an etching process of the fourth insulating layer 125 performed after forming the gate electrodes of the first transistor T1 and the first switching transistors ST1 on the fourth insulating layer 125, a large amount of oxygen vacancies may occur in the first electrode regions E1 and the second electrode regions E2 of the first transistor T1 and the first switching transistors ST1. Additionally, in the formation process of the fifth insulating layer 126 and/or a post-treatment process including heat treatment, hydrogen may be introduced into the first electrode regions E1 and the second electrode regions E2 of the first transistor T1 and the first switching transistors ST1, thereby increasing the carrier concentration (e.g., electron concentration) in the first electrode regions E1 and the second electrode regions E2 of the first transistor T1 and the first switching transistors ST1. Accordingly, the first electrode regions E1 and the second electrode regions E2 of the first transistor T1 and the first switching transistors ST1 may become appropriately conductive without performing a separate doping process. However, embodiments are not limited thereto, and other methods and/or materials may be used to increase the conductivity of the first electrode regions E1 and second electrode regions E2 of the second semiconductor patterns.

According to an embodiment, by forming at least one transistor included in the sub-pixels SPX using an oxide semiconductor, the operating characteristics of the sub-pixels SPX may be stabilized and/or improved. For example, by forming the first transistor T1 and at least one first switching transistor ST1 included in the sub-pixels SPX using an oxide semiconductor, the leakage current of the sub-pixels SPX may be reduced. Additionally, since an oxide transistor including an oxide semiconductor has the characteristics of low hysteresis and high temperature stability, the operating characteristics of the first transistor T1 may be improved by forming the first transistor T1 as an oxide transistor. Accordingly, the image quality and reliability of the display device 1 may be improved.

The fourth insulating layer 125 may be disposed on the second semiconductor patterns. The fourth insulating layer 125 may include at least one insulating material (e.g., an inorganic insulating material) and may be formed as a single layer or multiple layers.

In an embodiment, the fourth insulating layer 125 may have a shape and/or size corresponding to the gate electrodes of the first transistor T1 and the first switching transistors ST1, and may be partially disposed on only a portion (e.g., the channel region CH) of the active layer of each of the first transistor T1 and the first switching transistors ST1. In an embodiment, the fourth insulating layer 125 may first be formed over the entire display area DA or the like, and may be etched into a shape and/or size corresponding to the gate electrode of each of the first transistor T1 and the first switching transistors ST1 by an etching process performed after the gate electrodes of the first transistor T1 and the first switching transistors ST1 are formed. By etching the fourth insulating layer 125, the first electrode regions E1 and the second electrode regions E2 of the first transistor T1 and the first switching transistors ST1 may be appropriately or easily made conductive. However, embodiments are not limited thereto, and the fourth insulating layer 125 may be formed over the entire the display area DA.

Third conductive patterns (e.g., third gate patterns of a third conductive layer) including a conductive material may be disposed on the fourth insulating layer 125. The third conductive patterns may include the gate electrodes of the first transistor T1 and the first switching transistors ST1 included in the sub-pixels SPX. In an embodiment, the third conductive patterns may include the first gate electrode GE1 and a gate electrode GE6 of the sixth transistor T6 included in each of the sub-pixels SPX. The gate electrode GE6 of the sixth transistor T6 may also be referred to as “sixth gate electrode GE6.” In an embodiment, the third conductive patterns may further include the gate electrodes of the second, third, fourth, and seventh transistors T2, T3, T4, and T7, in addition to the first gate electrode GE1 and the sixth gate electrode GE6.

In an embodiment, by using third conductive patterns to integrally form both the gate electrodes of the oxide-based transistors (e.g., the first transistor T1 and first switching transistors ST1) and the sub-gate electrode BGE, layout efficiency can be improved while minimizing or reducing parasitic variation between transistors of different material types. For example, integrating the gate electrode GE1 of the first transistor T1 and the gate electrode GE6 of the sixth transistor T6 into a common conductive layer may help stabilize timing alignment across switching paths that influence signal write-in and light emission. This unified layer approach may also contribute to improved process uniformity during gate patterning in the display area DA.

The fifth insulating layer 126 may be disposed on the third conductive patterns. The fifth insulating layer 126 may include at least one insulating material (e.g., an inorganic insulating material) and may be formed as a single layer or multiple layers.

Fourth conductive patterns (e.g., first source-drain patterns of a fourth conductive layer) including a conductive material may be disposed on the fifth insulating layer 126. The fourth conductive patterns may include at least one electrode, a bridge pattern, and/or a wire. For example, the fourth conductive patterns may include first, second, third, fourth, and fifth connection electrodes CNE1, CNE2, CNE3, CNE4, and CNE5 electrically connected to at least one circuit element included in each of the sub-pixels SPX.

The first connection electrode CNE1 may be a conductive pattern that forms the first node N1 of FIG. 6. For example, the first connection electrode CNE1 may penetrate the fifth insulating layer 126 to be electrically connected to the first gate electrode GE1. The first connection electrode CNE1 may penetrate the second, third, and fifth insulating layers 123, 124, and 126 to be electrically connected to the second capacitor electrode CPE2. Accordingly, the first gate electrode GE1 and the second capacitor electrode CPE2 of each sub-pixel SPX may be electrically connected to each other. In an embodiment, the first gate electrode GE1 and the second capacitor electrode CPE2 may also be electrically connected to the second transistor T2 through at least one connection electrode and/or a contact hole.

The second connection electrode CNE2 may be a conductive pattern that forms the second node N2 of FIG. 6. For example, the second connection electrode CNE2 may penetrate the third and fifth insulating layers 124 and 126 to be electrically connected to the second electrode region E2 of the first transistor T1, the sub-gate electrode BGE of the first transistor T1, and the third capacitor electrode CPE3. In an embodiment, the second connection electrode CNE2 may penetrate the fifth insulating layer 126 to be electrically connected to the first electrode region E1 of the sixth transistor T6. For example, the second connection electrode CNE2, which is depicted as being divided into two patterns in the cross-sectional view of FIG. 7, may be a single connected pattern in plan view. In an embodiment, the first electrode region E1 of the sixth transistor T6 may be electrically connected to the second electrode region E2 of the first transistor T1, the sub-gate electrode BGE of the first transistor T1, and the third capacitor electrode CPE3 through another connection electrode that is separate from the second connection electrode CNE2. In an embodiment, the first active layer ACT1 and the sixth active layer ACT6 may be integrally formed.

In an embodiment, the electrical connection established by the second connection electrode CNE2 between the sub-gate electrode BGE and the second electrode region E2 of the first transistor T1 may also serve to tightly couple the sub-gate potential to the driving state of the oxide transistor. This coupling may reduce undesired variation in threshold voltage resulting from charge accumulation or environmental drift, which may improve the stability of current flow from the sixth transistor T6 to the light-emitting element LE. Additionally, by connecting the third capacitor electrode CPE3 through the same node, the first capacitor C1 can dynamically follow voltage fluctuations on node N2 without introducing phase misalignment, which may improve the gray-level accuracy of the display output.

The third connection electrode CNE3 may be a conductive pattern that connects the first transistor T1 to the fifth transistor T5. For example, the third connection electrode CNE3 may penetrate the fifth insulating layer 126 to be electrically connected to the first electrode region E1 of the first transistor T1, and may penetrate the first, second, third, and fifth insulating layers 122, 123, 124, and 126 to be electrically connected to the second electrode region E2 of the fifth transistor T5.

The fourth connection electrode CNE4 may be a conductive pattern that connects the fifth transistor T5 to the first power line VDL. For example, the fourth connection electrode CNE4 may penetrate the first, second, third, and fifth insulating layers 122, 123, 124, and 126 to be electrically connected to the first electrode region E1 of the fifth transistor T5. In an embodiment, the fourth connection electrode CNE4 may be electrically connected to the first power line VDL through at least one connection electrode and/or a contact hole. In an embodiment, the fourth connection electrode CNE4 may be a portion of the first power line VDL.

The fifth connection electrode CNE5 may be a conductive pattern that connects the sixth transistor T6 to the light-emitting element LE. For example, the fifth connection electrode CNE5 may penetrate the fifth insulating layer 126 to be electrically connected to the second electrode region E2 of the sixth transistor T6, and may be electrically connected to a first electrode ET1 of the light-emitting element LE through a sixth connection electrode CNE6. In an embodiment, the fifth connection electrode CNE5 may also be electrically connected to the fourth transistor T4 through at least one connection electrode and/or a contact hole. In an embodiment, the active layer of the fourth transistor T4 and the sixth active layer ACT6 may be integrally formed.

The sixth insulating layer 127 may be disposed on the fourth conductive patterns. The sixth insulating layer 127 may include at least one insulating material (e.g., acrylic resin, epoxy resin, phenolic resin, polyamide resin, polyimide resin, or another organic insulating material) and may be formed as a single layer or multiple layers.

Fifth conductive patterns (e.g., second source-drain patterns of a fifth conductive layer) including a conductive material may be disposed on the sixth insulating layer 127. The fifth conductive patterns may include at least one electrode, a bridge pattern, and/or a wire. For example, the fifth conductive patterns may include the sixth connection electrode CNE6, the data line DL, and the constant voltage line DCL electrically connected to at least one circuit element included in each of the sub-pixels SPX.

The sixth connection electrode CNE6 may be a conductive pattern that connects the sixth transistor T6 to the light-emitting element LE. For example, the sixth connection electrode CNE6 may penetrate the sixth insulating layer 127 to be electrically connected to the fifth connection electrode CNE5, and may be electrically connected to the second electrode region E2 of the sixth transistor T6 through the fifth connection electrode CNE5. The sixth connection electrode CNE6 may also be electrically connected to the fourth transistor T4.

The data line DL may be electrically connected to the second transistor T2. For example, the data line DL may be electrically connected to the second transistor T2 through at least one connection electrode and/or a contact hole.

The constant voltage line DCL may be one of the power lines PL electrically connected to the sub-pixel SPX. In an embodiment, the constant voltage line DCL may be the first power line VDL, but is not limited thereto. In an embodiment, the constant voltage line DCL may overlap the channel region CH of the first transistor T1. Accordingly, it is possible to reduce or prevent light from being incident on the channel region CH or the like of the first transistor T1 from above the first transistor T1. Additionally, the first, second, and third capacitor electrodes CPE1, CPE2, and CPE3 of the first capacitor C1 may be disposed below the channel region CH of the first transistor T1. Accordingly, it is possible to reduce or prevent light from being incident on the channel region CH or the like of the first transistor T1 from below the first transistor T1. According to an embodiment, by preventing light from entering the channel region CH or the like of the first transistor T1, the operating characteristics of the first transistor T1 may be stabilized and the operating characteristics of the sub-pixel SPX may be improved.

In an embodiment, since oxide semiconductors used in the first transistor T1 may be sensitive to ambient light and prone to threshold voltage shifts under illumination, overlapping the constant voltage line DCL and the capacitor electrodes below the channel region CH may aid in reducing photo-induced instability. This stacked configuration may provide bidirectional optical shielding, which may contribute to the long-term reliability and image uniformity of the display device.

A seventh insulating layer 128 may be disposed on the fifth conductive patterns. The seventh insulating layer 128 may include at least one insulating material (e.g., an organic insulating material) and may be formed as a single layer or multiple layers.

The conductive patterns included in each of the conductive layers of the backplane layer 120 may include at least one conductive material. For example, each of the first, second, third, fourth, and fifth conductive patterns included in the first conductive layer on the first insulating layer 122, the second conductive layer on the second insulating layer 123, the third conductive layer on the fourth insulating layer 125, the fourth conductive layer on the fifth insulating layer 126, and the fifth conductive layer on the sixth insulating layer 127 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), or another metal, an alloy thereof, or another conductive material. In an embodiment, the conductive patterns disposed in the same conductive layer may be simultaneously formed using the same conductive material. At least two conductive layers of the conductive layers of the backplane layer 120 may include the same conductive material or may include different conductive materials.

In an embodiment, the conductive patterns included in each of the conductive layers of the backplane layer 120 may have a single-layer or multi-layer structure. For example, each of the electrodes and/or wires included in the first, second, third, fourth, and fifth conductive patterns may have a single-layer or multi-layer structure. The conductive patterns included in at least two of the conductive layers of the backplane layer 120 may have the same cross-sectional structure or different cross-sectional structures.

The light-emitting element layer 130 may be disposed on the seventh insulating layer 128. The light-emitting element layer 130 may be disposed in the display area DA. For example, the light-emitting element layer 130 may be disposed on the backplane layer 120 in the display area DA.

The light-emitting element layer 130 may include the light-emitting elements LE of the sub-pixels SPX. For example, the light-emitting element layer 130 may include a pixel defining film 131 that partitions the emission areas EA of the sub-pixels SPX, and the light-emitting element LE disposed in each emission area EA. In an embodiment, the light-emitting element layer 130 may further include a spacer disposed on a portion of the pixel defining film 131.

The light-emitting element LE may include the first electrode ET1 (e.g., anode electrode) and a second electrode ET2 (e.g., cathode electrode) opposing each other, and a light-emitting layer EML disposed between the first electrode ET1 and the second electrode ET2. In an embodiment, the first electrode ET1, the light-emitting layer EML, and the second electrode ET2 may be sequentially stacked on the backplane layer 120 along the third direction DR3.

In an embodiment, the light-emitting element LE may further include at least one intermediate layer. For example, the light-emitting element LE may further include a first intermediate layer (e.g., a hole layer including a hole transport layer) interposed between the first electrode ET1 and the light-emitting layer EML, and a second intermediate layer (e.g., an electron layer including an electron transport layer) interposed between the light-emitting layer EML and the second electrode ET2. In an embodiment, at least one intermediate layer may be a common film formed across the entire display area DA.

Although FIG. 7 illustrates an embodiment in which the light-emitting element LE includes a single light-emitting layer EML, embodiments are not limited thereto. For example, the light-emitting element LE may be formed in a structure of two or more tandems including at least two light-emitting layers (e.g., the light-emitting layer EML of FIG. 7, and an additional light-emitting layer overlapping the light-emitting layer EML) that overlap each other in the third direction DR3. The light-emitting element LE may further include a charge generation layer interposed between the at least two light-emitting layers. The light-emitting layer EML may be provided in the form of a common film formed across the entire display area DA, or may be disposed in each emission area EA with a shape and/or size corresponding to each emission area EA.

In an embodiment, each of the sub-pixels SPX may include the light-emitting element LE that emits light of a color corresponding to the emission color (or emission wavelength) of the corresponding sub-pixel SPX. For example, a first sub-pixel SPX1 may include the light-emitting element LE of the first color (e.g., a red light-emitting element) that emits light of the first color, a second sub-pixel SPX2 may include the light-emitting element LE of the second color (e.g., a green light-emitting element) that emits light of the second color, and the third sub-pixel SPX3 may include the light-emitting element LE of the third color (e.g., a blue light-emitting element) that emits light of the third color.

In an embodiment, at least one sub-pixel SPX may include the light-emitting element LE that emits light of a different color from the emission color (or emission wavelength) of the corresponding sub-pixel SPX. In this case, the display panel 100 may further include a wavelength conversion layer (e.g., a wavelength conversion layer including a quantum dot of a size corresponding to the emission wavelength of the corresponding sub-pixel SPX) disposed on the light-emitting element LE that converts the color (or wavelength) of light emitted from the light-emitting element LE.

The first electrode ET1 of the light-emitting element LE may be disposed on the backplane layer 120. For example, the first electrode ET1 of the light-emitting element LE may be disposed on the seventh insulating layer 128 corresponding to each emission area EA. The first electrode ET1 of the light-emitting element LE may be electrically connected to the pixel circuit PXC of the corresponding sub-pixel SPX through at least one connection electrode. For example, the first electrode ET1 of the light-emitting element LE may penetrate the seventh insulating layer 128 to be electrically connected to the sixth connection electrode CNE6, and may be electrically connected to the sixth transistor T6 through the sixth connection electrode CNE6 and the fifth connection electrode CNE5 connected to the sixth connection electrode CNE6.

The first electrode ET1 of the light-emitting element LE may include at least one conductive material and may be formed as a single layer or multiple layers. In an embodiment, the first electrode ET1 of the light-emitting element LE may include a reflective electrode layer including a highly reflective metallic material. Accordingly, the light efficiency of the sub-pixel SPX may be increased.

The light-emitting layer EML of the light-emitting element LE may include a high molecular material or a low molecular material. Light emitted from the light-emitting layer EML may contribute to image display. In an embodiment, the light-emitting layer EML may be provided or formed for each sub-pixel SPX, and the light-emitting layer EML of each sub-pixel SPX may emit visible light of a color or wavelength corresponding to the corresponding sub-pixel SPX. In an embodiment, the light-emitting layer EML may be a common layer shared by the sub-pixels SPX of different colors, and a light conversion layer and/or color filters corresponding to the color (or wavelength) of light desired to be emitted from each sub-pixel SPX may be arranged in the emission areas EA of at least some of the sub-pixels SPX.

The second electrode ET2 of the light-emitting element LE may include a conductive material. In an embodiment, the second electrode ET2 of the light-emitting element LE may be a common layer formed across the entire display area DA to cover the light-emitting layer EML and the pixel defining film 131. In an embodiment, the second electrode ET2 of the light-emitting element LE may include transparent conductive oxide (TCO) such as ITO or IZO capable of transmitting light or a semi-transmissive conductive material such as magnesium (Mg), silver (Ag), or an alloy of magnesium (Mg) and silver (Ag).

The pixel defining film 131 may have an opening corresponding to each of the emission areas EA and may surround the emission areas EA. For example, the pixel defining film 131 may cover an edge of the first electrode ET1 of the light-emitting element LE and may include an opening exposing another portion of the first electrode ET1. A region where the exposed first electrode ET1 and the light-emitting layer EML overlap (or a region including the same) may be defined as the emission area EA of each sub-pixel SPX.

In an embodiment, the pixel defining film 131 may include an organic insulating material. For example, the pixel defining film 131 may include acrylic resin, epoxy resin, phenolic resin, polyamide resin, polyimide resin, unsaturated polyester resin, polyphenylene ether resin, polyphenylenesulfide resin, benzocyclobutene (BCB), or other organic insulating materials.

The encapsulation layer 140 may be disposed on the light-emitting element layer 130. The encapsulation layer 140 may cover the light-emitting element layer 130 in the display area DA and may extend to the non-display area NDA to be in contact with the backplane layer 120. For example, the encapsulation layer 140 may be disposed in the display area DA to cover the light-emitting element layer 130, and the end of the encapsulation layer 140 may be disposed in a portion of the non-display area NDA adjacent to the display area DA. The encapsulation layer 140 may block the permeation of oxygen or moisture into the light-emitting element layer 130, and may mitigate electrical and/or physical impacts to the backplane layer 120 and the light-emitting element layer 130.

In an embodiment, the encapsulation layer 140 may be formed as multiple layers including an inorganic encapsulation layer and an organic encapsulation layer. For example, the encapsulation layer 140 may include a first inorganic encapsulation layer 141, an organic encapsulation layer 143, and a second inorganic encapsulation layer 145 sequentially arranged on the light-emitting element layer 130. The encapsulation layer 140 may be redisposed by an encapsulation member of a different type, structure and/or material. For example, the light-emitting element layer 130 may be encapsulated using an upper substrate including an insulating material such as glass, or a protective layer including a single or multilayer capping layer.

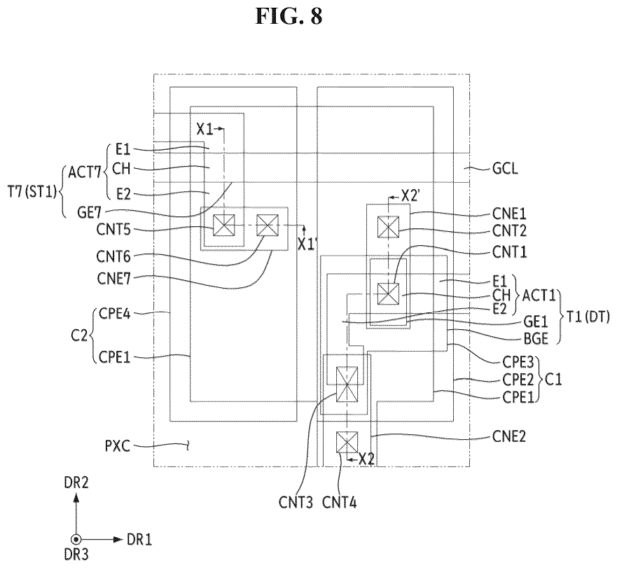

FIG. 8 is a plan view illustrating a part of a sub-pixel according to an embodiment. For example, FIG. 8 shows an embodiment of a layout for a portion of the sub-pixel SPX where the first transistor T1, the seventh transistor T7, the first capacitor C1, and the second capacitor C2 of FIG. 6 are disposed.

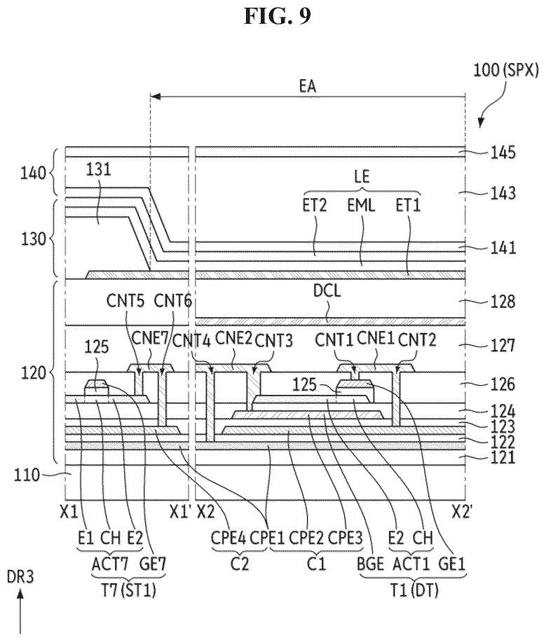

FIG. 9 is a cross-sectional view illustrating a cross-section of a sub-pixel according to an embodiment. For example, FIG. 9 shows an embodiment of a cross-section for a portion of the sub-pixel SPX along lines X1-X1′ and X2-X2′ of FIG. 8.

Referring to FIGS. 8 and 9 in addition to FIGS. 6 and 7, the first capacitor C1 and the second capacitor C2 may be disposed around the first transistor T1 and the seventh transistor T7. For example, the first capacitor C1 and the second capacitor C2 may be disposed below the first transistor T1 and the seventh transistor T7, respectively. Additionally, the first capacitor C1 and the second capacitor C2 may be electrically connected to the first transistor T1 and the seventh transistor T7, respectively.

In an embodiment, the first capacitor C1 and the second capacitor C2 may share the first capacitor electrode CPE1. For example, a portion (also referred to as “first portion” of the first capacitor electrode CPE1) of the first capacitor electrode CPE1 may overlap the second capacitor electrode CPE2 and the third capacitor electrode CPE3, and the first capacitor C1 may be formed in a region where the first capacitor electrode CPE1, the second capacitor electrode CPE2, and the third capacitor electrode CPE3 overlap each other. Another portion (also referred to as “second portion” of the first capacitor electrode CPE1) of the first capacitor electrode CPE1 may overlap the fourth capacitor electrode CPE4, and the second capacitor C2 may be formed in a region where the first capacitor electrode CPE1 and the fourth capacitor electrode CPE4 overlap each other.

The first transistor T1 may be disposed above the first capacitor C1, and the seventh transistor T7 may be disposed above the second capacitor C2. In an embodiment, a portion of the first capacitor C1 and a portion of the first transistor T1 may be integrally formed. In an embodiment, the third capacitor electrode CPE3 of the first capacitor C1 and the sub-gate electrode BGE of the first transistor T1 may be formed in substantially a single conductive pattern.

The first gate electrode GE1 and the second capacitor electrode CPE2 may be electrically connected to each other through the first connection electrode CNE1.

The first connection electrode CNE1 may be connected to the first gate electrode GE1 through a first contact hole CNT1 formed in the fifth insulating layer 126. Additionally, the first connection electrode CNE1 may be connected to the second capacitor electrode CPE2 through a second contact hole CNT2 formed in the second, third, and fifth insulating layers 123, 124, and 126.

The first capacitor electrode CPE1 and the third capacitor electrode CPE3 may be electrically connected to each other through the second connection electrode CNE2. The first capacitor electrode CPE1 and the third capacitor electrode CPE3 may form one electrode of the first capacitor C1 connected to the second node N2.

The second connection electrode CNE2 may be connected to the second electrode region E2 of the first transistor T1 and the third capacitor electrode CPE3 through a third contact hole CNT3 formed in the third and fifth insulating layers 124 and 126. Additionally, the second connection electrode CNE2 may be connected to the first capacitor electrode CPE1 through a fourth contact hole CNT4 formed in the first, second, third, and fifth insulating layers 122, 123, 124, and 126.

The seventh transistor T7 may include an active layer ACT7 disposed on the third insulating layer 124, and a gate electrode GE7 disposed on the fourth insulating layer 125 covering the active layer ACT7. The active layer ACT7 of the seventh transistor T7 may also be referred to as “seventh active layer ACT7.” The gate electrode GE7 of the seventh transistor T7 may also be referred to as “seventh gate electrode GE7.” The seventh active layer ACT7 may include the channel region CH overlapping the seventh gate electrode GE7, and the first electrode region E1 and the second electrode region E2 disposed on different sides of the channel region CH. The first electrode region E1 of the seventh active layer ACT7 may be electrically connected to the reference voltage line VRL. The second electrode region E2 of the seventh active layer ACT7 may be electrically connected to the fourth capacitor electrode CPE4 through a seventh connection electrode CNE7. The seventh gate electrode GE7 may be electrically connected to the gate control line GCL.

The seventh connection electrode CNE7 may be connected to the second electrode region E2 of the seventh transistor T7 through a fifth contact hole CNT5 formed in the fifth insulating layer 126. Additionally, the seventh connection electrode CNE7 may be connected to the fourth capacitor electrode CPE4 through a sixth contact hole CNT6 formed in the second, third, and fifth insulating layers 123, 124, and 126.

As described above, the sub-pixel SPX and the pixel PX including the sub-pixel SPX according to embodiments may include the first transistor T1, and the third capacitor electrode CPE3 disposed below the first active layer ACT1 of the first transistor T1 and electrically connected to the second electrode region E2 of the first transistor T1. In some embodiments, the sub-pixel SPX and the pixel PX including the sub-pixel SPX may further include the first capacitor electrode CPE1 disposed below the third capacitor electrode CPE3 and electrically connected to the third capacitor electrode CPE3, and the second capacitor electrode CPE2 disposed between the first capacitor electrode CPE1 and the third capacitor electrode CPE3. In some embodiments, the first capacitor electrode CPE1 may include the first semiconductor material (e.g., polycrystalline silicon) included in the active layers of some (e.g., the second switching transistors ST2) of the transistors formed in the backplane layer 120, and the first active layer ACT1 of the first transistor T1 may include the second semiconductor material (e.g., an oxide semiconductor advantageous in ensuring the reliability of the first transistor T1). According to embodiments, the design structure of the backplane layer 120 including the circuit elements of the sub-pixel SPX may be improved, and the operating characteristics of the sub-pixel SPX and the pixel PX including the sub-pixel SPX may be improved.

For example, according to embodiments, at least one capacitor (e.g., the first capacitor C1 and the second capacitor C2) included in the sub-pixel SPX may be formed by utilizing the first capacitor electrode CPE1 electrically connected to the second electrode region E2 (e.g., the source region or source electrode of the first transistor T1) of the first transistor T1 and formed in the same layer as the fifth active layer ACT5 using polycrystalline silicon. Accordingly, the circuit elements of the sub-pixel SPX may be efficiently arranged.

In some embodiments, the first transistor T1 may be an oxide transistor including an oxide semiconductor. Accordingly, the operating characteristics of the first transistor T1 and the sub-pixel SPX including the first transistor T1 may be improved.

In some embodiments, the third capacitor electrode CPE3 may be disposed below the first active layer ACT1 of the first transistor T1, and the third capacitor electrode CPE3 may be electrically connected to the second electrode region E2 of the first transistor T1. Accordingly, the third capacitor electrode CPE3 may be used as the sub-gate electrode BGE for adjusting the characteristics of the first transistor T1.

In some embodiments, the thickness of the third insulating layer 124 may be adjusted to appropriately and/or easily adjust the operating characteristics of the first transistor T1. For example, by appropriately reducing the thickness of the third insulating layer 124, the sensitivity of the current-voltage variation of the first transistor T1 may be reduced and the operating characteristics of the first transistor T1 may be improved.

In some embodiments, one electrode of the first capacitor C1 may include multiple layers. In an embodiment, one electrode of the first capacitor C1 may include the first capacitor electrode CPE1 and the third capacitor electrode CPE3 that are electrically connected to each other through the second connection electrode CNE2. Additionally, another electrode, e.g., the second capacitor electrode CPE2, of the first capacitor C1 may be disposed between the first capacitor electrode CPE1 and the third capacitor electrode CPE3. Accordingly, a suitable capacitance of the first capacitor C1 may be appropriately and/or sufficiently secured by the capacitance formed between the first capacitor electrode CPE1 and the second capacitor electrode CPE2, and between the second capacitor electrode CPE2 and the third capacitor electrode CPE3, and connected in parallel with each other. Accordingly, the formation area of the first capacitor C1 may be reduced or minimized while appropriately securing the capacitance of the first capacitor C1.

As the formation area of the first capacitor C1 is reduced, parasitic capacitance between the first capacitor C1 and other peripheral circuit elements or wires except for the first transistor T1 may be reduced or prevented. For example, in an embodiment, the third capacitor electrode CPE3 of the first capacitor C1 does not overlap other peripheral circuit elements or wires except for the first transistor T1, and in embodiments, the overlapping area may be reduced. Accordingly, even if the thickness of the third insulating layer 124 is reduced, coupling effects (e.g., signal interference) that may be caused by the third capacitor electrode CPE3 and other peripheral circuit elements or wires may be prevented or reduced, and the operating characteristics of the sub-pixel SPX may be stabilized.

In some embodiments, the first capacitor C1 and the second capacitor C2 may share one capacitor electrode and may be disposed adjacent to each other. In an embodiment, the first capacitor C1 and the second capacitor C2 may share the first capacitor electrode CPE1 disposed in the same layer as the fifth active layer ACT5.

According to embodiments, the circuit elements of each sub-pixel SPX may be efficiently arranged inside the backplane layer 120 and the design structure of the backplane layer 120 may be improved. Accordingly, even in the high-resolution display device 1 where the area of each of the sub-pixels SPX is reduced or limited, the circuit elements may be appropriately or easily arranged in each sub-pixel area, and electrical stability between the circuit elements may be ensured.

Thus, according to embodiments, the stacked capacitor structure, shared electrode architecture, and sub-gate-integrated driving transistor configuration provided herein may collectively enable a pixel circuit design that supports compact layout, high capacitance density, and improved transistor control. These features may applicable in high-resolution displays for which stable operation at low luminance levels is desired. By integrating the capacitive and driving elements in a vertically layered manner and improving the interconnection scheme, as described in embodiments above, circuit performance, image uniformity, and fabrication scalability may all be improved within sub-pixel areas.

In an embodiment, the display device 1 may include the substrate 110 and the pixel PX disposed on the substrate 110. The pixel PX may include the first transistor T1 and the first capacitor C1, which overlap each other. The first capacitor C1 may include the first capacitor electrode CPE1 disposed on the substrate 110, the second capacitor electrode CPE2 disposed on the first insulating layer 122 that is interposed between the first capacitor electrode CPE1 and the second capacitor electrode CPE2, and the third capacitor electrode CPE3 disposed on the second insulating layer 123 that is interposed between the second capacitor electrode CPE2 and the third capacitor electrode CPE3.

The third capacitor electrode CPE3 may be electrically connected to the first capacitor electrode CPE1 via the connection electrode CNE2. The first transistor T1 may include the first active layer ACT1 disposed on the third insulating layer 124 that is interposed between the first active layer ACT1 and the third capacitor electrode CPE3. The first active layer ACT1 may include the channel region CH, the first electrode region E1 disposed at one side of the channel region CH, and the second electrode region E2 disposed at another side of the channel region CH. The first transistor T1 may also include the first gate electrode GE1 disposed on the fourth insulating layer 125 that is interposed between the channel region CH and the first gate electrode GE1. In this structure, the third capacitor electrode CPE3 may be electrically connected to the second electrode region E2 and may be configured to function as the sub-gate electrode that adjusts a current-voltage characteristic of the first transistor T1.

The display device 1 (or the display module 11) according to at least one of the above-described embodiments may be applied to various electronic devices. An electronic device according to an embodiment may include the display device 1 or the display module 11 described above, and may further include a module or a device having other additional functions, in addition to the display device 1 or the display module 11.

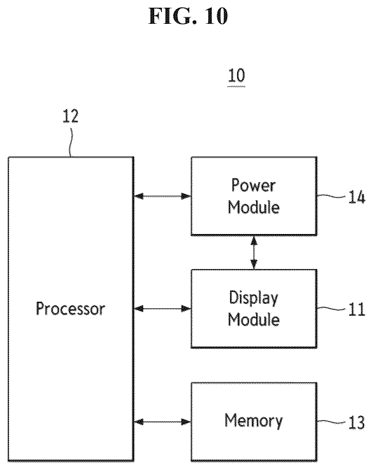

FIG. 10 is a block diagram of an electronic device according to an embodiment. Referring to FIG. 10, the electronic device 10 according to an embodiment may include a display module 11, a processor 12, a memory 13, and a power module 14.

The electronic device 10 may output various information in the form of images through the display module 11. For example, when the processor 12 executes an application stored in the memory 13, image information provided by the application may be provided to a user through the display module 11.

The processor 12 may include at least one of, for example, a central processing unit (CPU), an application processor (AP), a graphic processing unit (GPU), a communication processor (CP), an image signal processor (ISP), or a controller.

The memory 13 may store data information utilized for the operation of the processor 12 or the display module 11. For example, the memory 13 may store an image data signal and/or an input control signal.

The processor 12 may control the display module 11 using information stored in the memory 13. The processor 12 may transmit the image data signal and/or the input control signal stored in the memory 13 to the display module 11. For example, when the processor 12 executes an application stored in the memory 15, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power utilized for the operation of the electronic device 10.

At least one of the components of the electronic device 10 described above may be included in the display device 1 according to the embodiments described above. Further, some of individual modules functionally included in one module may be included in the display device and some others may be provided separately from the display device 1. For example, the display device 1 may include the display module 11, and the processor 12, the memory 13, and the power module 14 may be provided in the form of other devices in the electronic device 10 other than the display device 1.

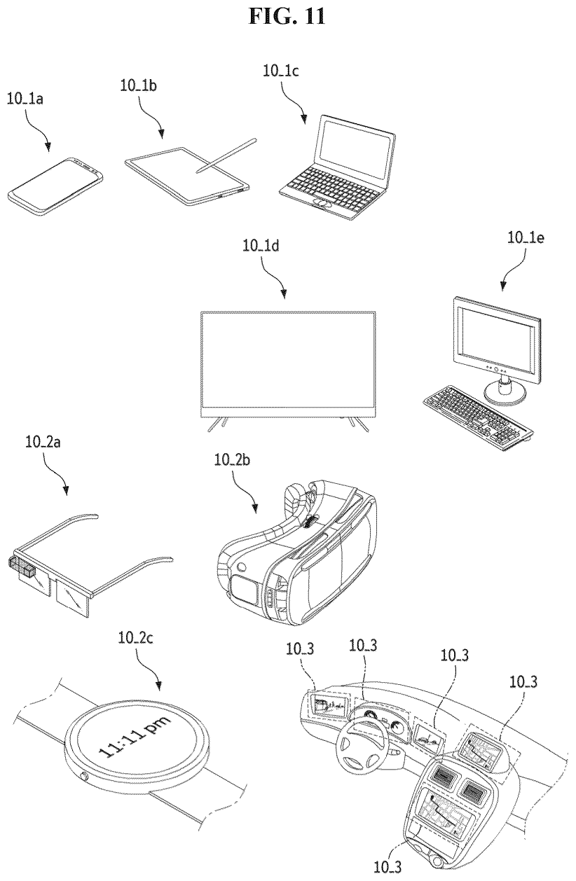

FIG. 11 illustrates schematic views of electronic devices according to various embodiments.

Referring to FIG. 11, various electronic devices to which the display device 1 according to embodiments may be applied may include not only an image display electronic device such as, for example, a smartphone 10_1a, a tablet PC 10_1b, a laptop 10_1c, a TV 10_1d, and a desktop monitor 10_1e, but also a wearable electronic device including a display module, such as, for example, smart glasses 10_2a, a head mounted display 10_2b, or a smart watch 10_2c, a vehicle electronic device 10_3 including a display module, such as, for example, a room mirror display, a center information display (CID) disposed on a dashboard, a center fascia, and an instrument panel of an automobile, and the like.

As is traditional in the field of the present disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. In embodiments, each block, unit and/or module may be implemented by dedicated hardware, or as a combination of dedicated hardware to perform some functions and a processor (e.g., one or more programmed microprocessors and associated circuitry) to perform other functions.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device, comprising:
a substrate; and
a pixel on the substrate and comprising a first transistor and a first capacitor that overlap each other,
wherein the first capacitor comprises:
a first capacitor electrode on the substrate;
a second capacitor electrode on a first insulating layer, the first insulating layer arranged between the first capacitor electrode and the second capacitor electrode; and
a third capacitor electrode on a second insulating layer and electrically connected to the first capacitor electrode, the second insulating layer arranged between the second capacitor electrode and the third capacitor electrode,
wherein the first transistor comprises:
a first active layer on a third insulating layer, the third insulating layer arranged between the first active layer and the third capacitor electrode,
wherein the first active layer comprises a channel region, a first electrode region at a side of the channel region, and a second electrode region at another side of the channel region; and
a gate electrode on a fourth insulating layer, the fourth insulating layer arranged between the channel region and the gate electrode,
wherein the third capacitor electrode is electrically connected to the second electrode region and is configured to function as a sub-gate electrode to adjust a current-voltage characteristic of the first transistor.

2. The display device of claim 1, wherein the first capacitor electrode includes a first semiconductor material and a conductive dopant doped into the first semiconductor material.

3. The display device of claim 2, wherein the first active layer includes a second semiconductor material different from the first semiconductor material.

4. The display device of claim 3, wherein the first semiconductor material includes a polycrystalline silicon, and
the second semiconductor material includes an oxide semiconductor.

5. The display device of claim 2, wherein each of the second capacitor electrode and the third capacitor electrode includes a conductive material.

6. The display device of claim 1, wherein the gate electrode is electrically connected to the second capacitor electrode.

7. The display device of claim 1, wherein the third capacitor electrode and the gate electrode face each other, and the channel region of the first active layer is interposed between the third capacitor electrode and the gate electrode.

8. The display device of claim 1, wherein the pixel further comprises a first switching transistor comprising a second active layer in a same first layer as the first active layer.

9. The display device of claim 8, wherein the first capacitor electrode comprises a first portion overlapping the first transistor and a second portion overlapping the first switching transistor.

10. The display device of claim 9, wherein the pixel further comprises a second capacitor comprising a second portion of the first capacitor electrode and a fourth capacitor electrode overlapping the second portion of the first capacitor electrode.

11. The display device of claim 8, wherein the first active layer and the second active layer include an oxide semiconductor.

12. The display device of claim 8, wherein the pixel further comprises a second switching transistor comprising a third active layer in a same second layer as the first capacitor electrode.

13. The display device of claim 12, wherein the first capacitor electrode and the third active layer include a polycrystalline silicon.

14. The display device of claim 1, wherein the pixel further comprises a light-emitting element electrically connected to a pixel circuit comprising the first transistor and the first capacitor.

15. An electronic device, comprising:
a display device comprising a display panel;
a memory configured to store an image data signal or an input control signal; and
a processor configured to transmit the image data signal or the input control signal stored in the memory to the display device,
wherein the display panel comprises a substrate, and a pixel on the substrate and comprising a first transistor and a first capacitor that overlap each other,
wherein the first capacitor comprises:
a first capacitor electrode on the substrate;
a second capacitor electrode on a first insulating layer, the first insulating layer arranged between the first capacitor electrode and the second capacitor electrode; and
a third capacitor electrode on a second insulating layer and electrically connected to the first capacitor electrode, the second insulating layer arranged between the second capacitor electrode and the third capacitor electrode,
wherein the first transistor comprises:
a first active layer on a third insulating layer, the third insulating layer arranged between the first active layer and the third capacitor electrode,
wherein the first active layer comprises a channel region, a first electrode region at a side of the channel region, and a second electrode region at another side of the channel region; and
a gate electrode on a fourth insulating layer, the fourth insulating layer arranged between the channel region and the gate electrode,
wherein the third capacitor electrode is electrically connected to the second electrode region and is configured to function as a sub-gate electrode to adjust a current-voltage characteristic of the first transistor.

16. The electronic device of claim 15, wherein the first capacitor electrode includes a first semiconductor material and a conductive dopant doped into the first semiconductor material.

17. The electronic device of claim 16, wherein the first active layer includes a second semiconductor material different from the first semiconductor material,
the first semiconductor material includes a polycrystalline silicon, and
the second semiconductor material includes an oxide semiconductor.

18. The electronic device of claim 15, wherein the third capacitor electrode and the gate electrode face each other, and the channel region of the first active layer is interposed between the third capacitor electrode and the gate electrode.

19. The electronic device of claim 15, wherein the pixel further comprises a first switching transistor comprising a second active layer in a same layer as the first active layer, and
the first capacitor electrode comprises a first portion overlapping the first transistor and a second portion overlapping the first switching transistor.

20. The electronic device of claim 19, wherein the pixel further comprises a second capacitor comprising a second portion of the first capacitor electrode and a fourth capacitor electrode overlapping the second portion of the first capacitor electrode.
